(19) United States
(12) Patent Application Publication
(10) Pub. No.: US 2025/0338533 A1
(43) Pub. Date: Oct. 30, 2025

(54) ISOLATION STRUCTURES IN TRANSISTOR DEVICES AND METHODS OF FORMING

(71) Applicant: Taiwan Semiconductor Manufacturing Co., Ltd., Hsinchu (TW)

(72) Inventors: Yu-Wei Chou, Hsinchu (TW); Ching-Hung Chen, Houlong Township (TW); Yen-Chun Huang, Taipei (TW); Zhen-Cheng Wu, Hsinchu (TW); Tze-Liang Lee, Hsinchu (TW)

(21) Appl. No.: 19/261,321

(22) Filed: Jul. 7, 2025

Related U.S. Application Data
(63) Continuation of application No. 18/643,324, filed on Apr. 23, 2024.
(60) Provisional application No. 63/617,100, filed on Jan. 3, 2024.

(51) Int. Cl. H10D 30/43; H01L 21/762; H10D 30/01; H10D 30/67; H10D 62/10

(52) U.S. Cl. CPC H10D 30/43; H01L 21/76224; H10D 30/014; H10D 30/6735; H10D 62/121

(57) ABSTRACT

A device, includes a first semiconductor fin and a second semiconductor fin; an isolation structure between the first semiconductor fin and the second semiconductor fin, the isolation structure comprising: an inner shallow trench isolation (STI) region; a first liner layer along sidewalls and a bottom surface of the inner STI region; and a STI hard mask on a top surface of the inner STI region. The STI hard mask and the first liner layer each comprise a higher concentration of nitrogen than the inner STI region.

### PRIORITY CLAIM AND CROSS-REFERENCE

This application is a continuation of U.S. application Ser. No. 18/643,324, filed on Apr. 23, 2024, which claims the benefit of U.S. Provisional Application No. 63/617,100, filed on Jan. 3, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3A, 3B, 3C, 4, 5, 6, 7, 8, 9, 10, 11, 12, 13A, 13B, 14A, 14B, 15A, 15B, 16A, 16B, 17A, 17B, 18A, 18B, 18C, 19A, 19B, 19C, 19D, 20A, 20B, 20C, 21A, 21B, 22A, 22B, 23A, 23B, 23C, 24A, 24B, 25A, 25B, 25C, 26A, 26B, 26C, 27A, 27B, 27C are cross-sectional views of intermediate stages in the manufacturing of nano-FETs, in accordance with some embodiments.

FIGS. 28A, 28B, and 28C illustrate varying cross-sectional views of a nano-FET in accordance with some embodiments.

FIGS. 29A, 29B, and 29C illustrate varying cross-sectional views of a nano-FET in accordance with some embodiments.

FIGS. 30A, 30B, and 30C illustrate varying cross-sectional views of a nano-FET in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, isolation regions (e.g., shallow trench isolation (STI) regions) are formed between and around fins of a transistor to provide isolation between various active regions of the transistor and to isolate the transistor from other, adjacent transistors in an integrated circuit die. Protective liners may be formed to cover sidewalls, a bottom surface, and a top surface of the isolation region to reduce isolation loss during subsequent cleaning and/or etching processes that are performed to fabricate the transistor. The outer, protective liners may be nitride layers when the inner, isolation region is made of an oxide. In this manner, the protective liners can provide etch selectivity to the encapsulated isolation regions and reduce isolation loss (e.g., STI loss) during subsequently applied cleaning/etching processes. Further, the nitrogen concentration of the protective liners can be adjusted depending on an acceptable tolerance for isolation loss, which allows embodiment methods to be selectively tuned to achieve a desired device configuration. As a result, manufacturing defects can be reduced, and electrical performance of the resulting device can be improved.

Embodiments are described below in a particular context, a die comprising nano- FETs. Various embodiments may be applied, however, to dies comprising other types of transistors (e.g., fin field effect transistors (FinFETs), planar transistors, or the like) in lieu of or in combination with the nano-FETs.

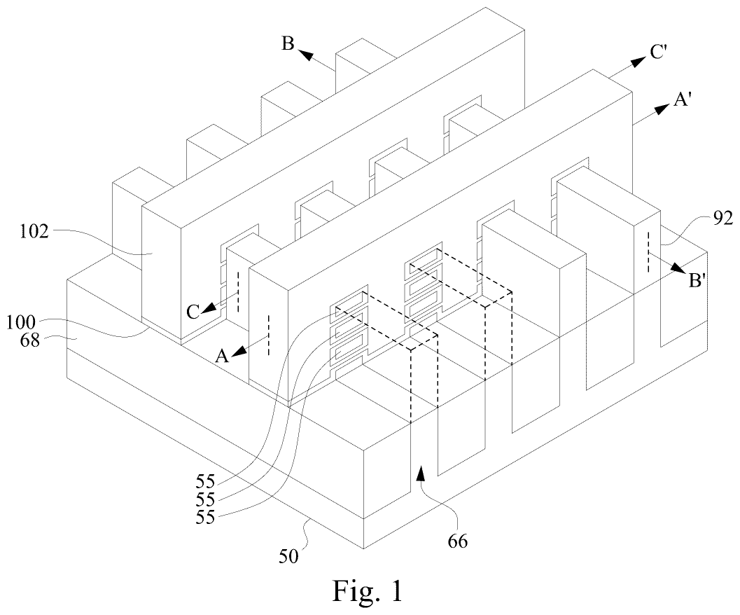

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation structures 68 (also referred to as STI structures 68) are disposed between adjacent fins 66, which may protrude above and from between neighboring isolation structures 68. In FIG. 1, the isolation structures 68 are illustrated as a single layer. However, as will be described in subsequent paragraphs, in various embodiments, the isolation structures 68 is a multi-layer structure comprising, for example, protective liners that cover sidewalls and lateral surfaces of an internal isolation region. Although the isolation structures 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation structures 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano- FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

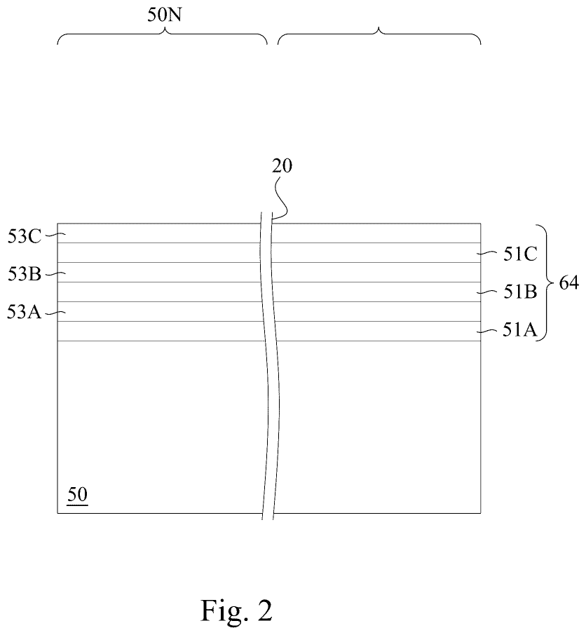

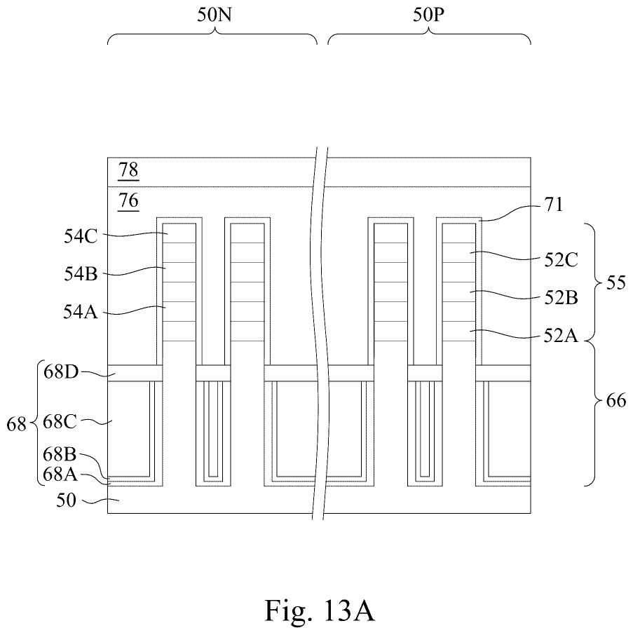

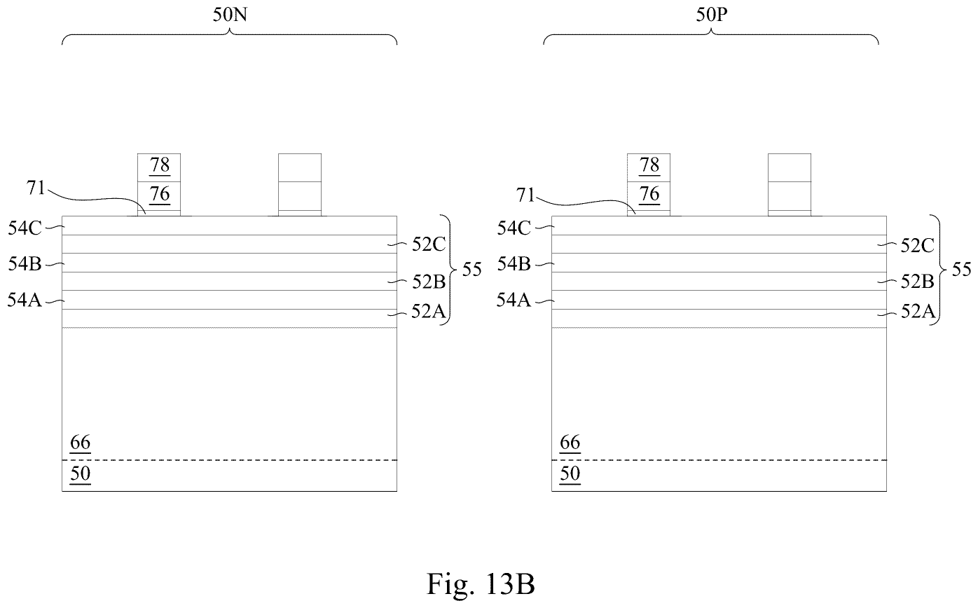

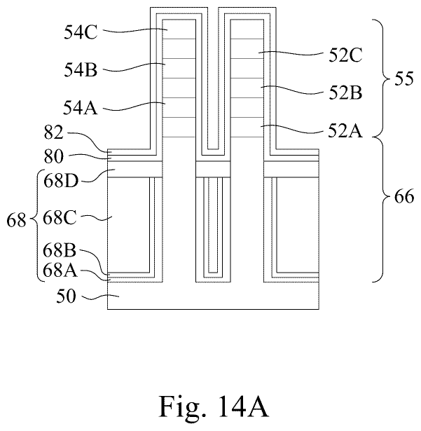

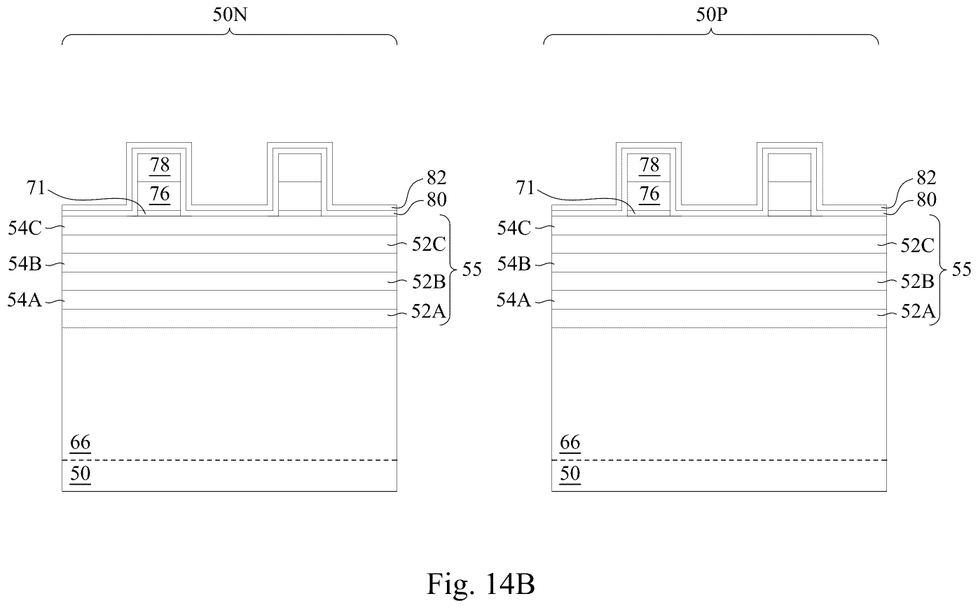

FIGS. 2 through 27C are cross-sectional views of intermediate stages in the manufacturing of nano-FETs, in accordance with some embodiments. FIGS. 2, 3A, 3B, 3C, 4 through 12, 13A, 20A, 21A, 22A, 23A, 24A, 25A, 26A, and 27A illustrate reference cross-section A-A′ illustrated in FIG. 1. FIGS. 13B, 14B, 15B, 16B, 17B, 18B, 18C, 19B, 19D, 20B, 21B, 22B, 23B, 24B, 25B, 26B, and 27B illustrate reference cross-section B-B′ illustrated in FIG. 1. FIGS. 14A, 15A, 16A, 17A, 18A, 19A, 19C, 20C, 25C, 26C, and 27C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

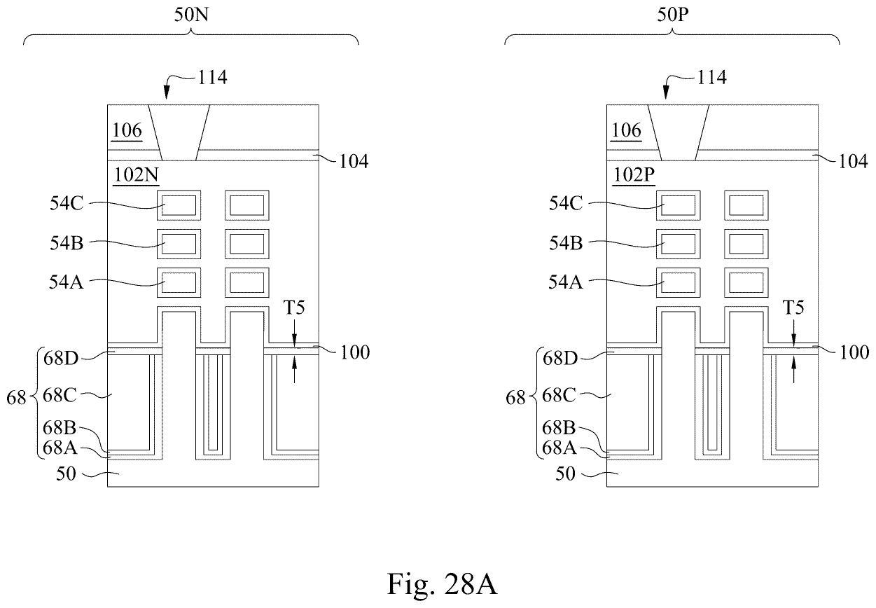

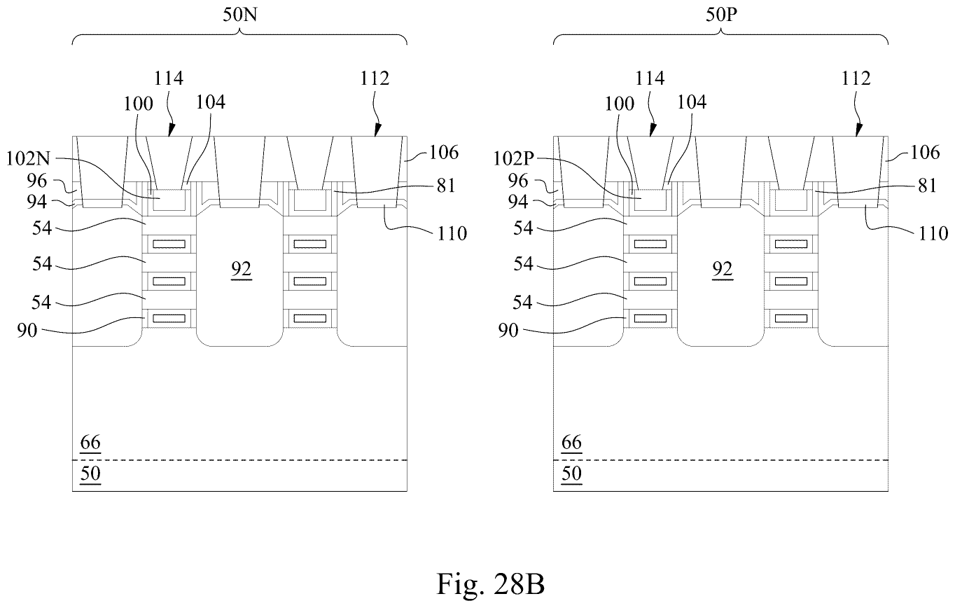

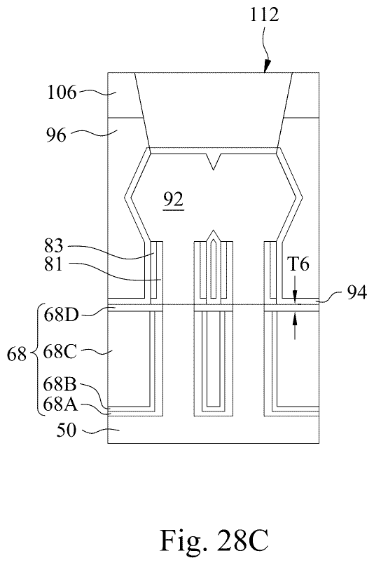

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or the another semiconductor material) and be formed simultaneously. FIGS. 28A, 28B, and 28C illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

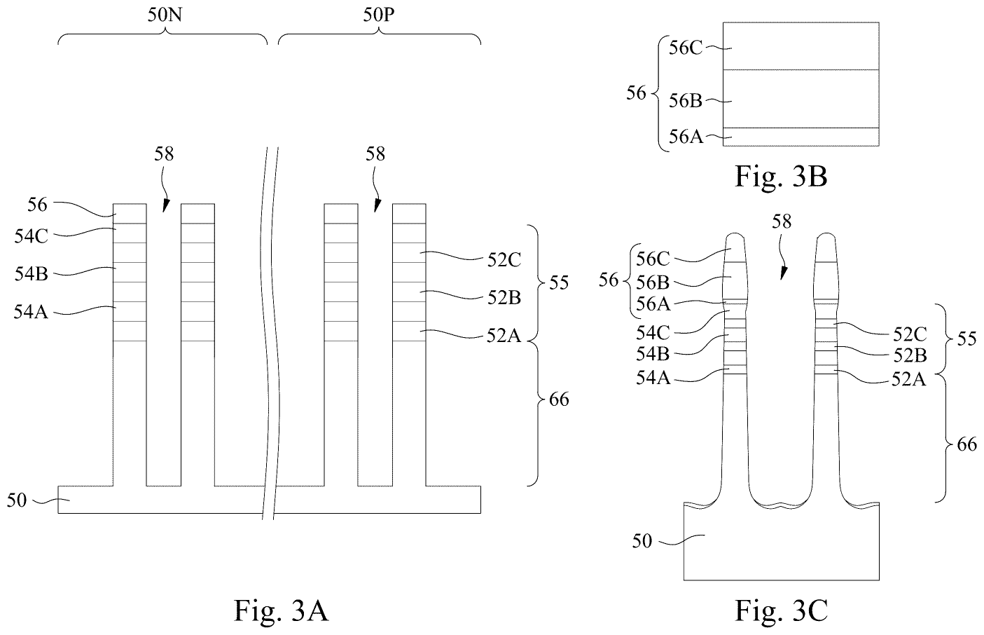

Referring now to FIGS. 3A-3C, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments, as illustrated by the detailed view of the hard mask 56 in FIG. 3B, the hard mask 56 may be a multi-layer structure. For example, the hard mask 56 may comprise an interfacial oxide layer 56A, a nitride layer 56B (e.g., a silicon nitride layer) over the interfacial oxide layer 56A, and an oxide layer 56C (e.g., a silicon oxide layer) over the nitride layer 56B. Other combinations of layer(s) that make up the hard mask 56 may be used in other embodiments. Each layer of the hard mask 56 may be formed over the nanostructures 55 using an acceptable process such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

FIG. 3A illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while FIG. 3A illustrates each of the fins 66 and the nanostructures 55 as having a consistent width throughout, in other embodiments (e.g., see FIG. 3C), the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape. Still further, a bottom surface of the trenches 58 between the fins 66 may be rounded and include concave and/or convex portions as illustrated by FIG. 3C. For ease of illustration only, subsequent process steps are illustrated with respect to the specific structures of FIG. 3A, but embodiments are equally applicable to the structure of FIG. 3C or other fin/nanostructure configurations.

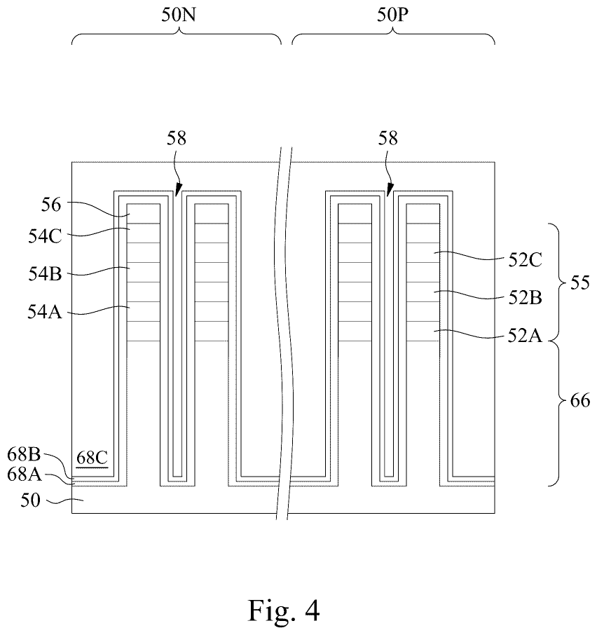

In FIGS. 4 through 11, isolation structures 68 are formed in the trenches 58 and adjacent the fins 66. The isolation structures 68 may be formed by depositing layers of insulation material over the substrate 50, the fins 66, the nanostructures 55, and the hard masks 56, and then patterning the layers of insulation material below the nanostructures 55. Referring first to FIG. 4, a first liner layer 68A is deposited along sidewalls and bottom surfaces of the trenches 58 over upper surfaces of the substrate 50, the fins 66, the nanostructures 55, and the hard masks 56 and along sidewalls of the fins 66, the nanostructures 55, and the hard masks 56. The first liner layer 68A may be an oxide layer, such as a silicon oxide layer or the like, that can be formed by any suitable process such as a thermal oxidation process, CVD, ALD, or the like. In some embodiments, the first liner layer 68A has a multilayer structure with an oxide layer formed over a semiconductor layer (e.g., a silicon layer). In such embodiments, the semiconductor layer may first be formed on sidewalls and a bottom surface of the trenches 58 by CVD, ALD, VPE, MBE, or the like. Then the oxide layer (e.g., a silicon oxide layer) may be formed over the semiconductor layer using the processes described above.

After the first liner layer 68A is deposited, a second liner layer 68B is deposited over the first liner layer 68A and along sidewalls and bottom surfaces of the trenches 58. The second liner layer 68B may extend over upper surfaces of the substrate 50, the fins 66, the nanostructures 55, and the hard masks 56 and along sidewalls of the fins 66, the nanostructures 55, and the hard masks 56. The first liner layer 68A may be a nitride layer, such as a silicon nitride layer, a silicon oxynitride layer, a silicon oxycarbonitride layer, or the like, that can be deposited by any suitable deposition process such as CVD, ALD, or the like. In a specific embodiment, the second liner layer 68B is a SiON layer or a SiCON layer with an atomic percentage of silicon in a range of 28% to 38%; an atomic percentage of carbon in a range of 0% to 8%; an atomic percentage of oxygen in a range of 50% to 60%; and an atomic percentage of nitrogen in a range of 4% to 13%. For example, the second liner layer 68B may comprise 33 at % silicon, 3 at % carbon, 55 at % oxygen, and 9 at % nitrogen. In some embodiments, the second liner layer 68B is deposited by an ALD process at a temperature in a range of 550° C. to 650° C. During the ALD process, a silicon-based precursor, a nitrogen-based precursor, and O₂ may be flowed to form the second liner layer 68B.

An inner shallow trench isolation (STI) material 68C is then formed over the second liner layer 68B to overfill remaining portions of the trenches 58. The STI material 68C may include an oxide, such as silicon oxide or the like high-density plasma CVD (HDP-CVD), flowable CVD (FCVD), the like, or a combination thereof. Other insulation materials formed by any acceptable process may be used. In embodiments where the STI material 68C is formed by an FCVD process, an anneal process may be performed once the insulation material is formed. The anneal process may cause diffusion of nitrogen away from the second liner layer 68B into the overlying STI material 68C as well as the underlying first liner layer 68A. However, a concentration of nitrogen may remain the highest within the second liner layer 68B amongst the first liner layer 68A, the second liner layer 68B, and the STI material 68C even after annealing. Specifically, a nitrogen peak may be detected sandwiched between the surrounding oxide layers of the STI material 68C and the first liner layer 68A. The first liner layer 68A may be used as a buffer layer to protect the fins 66 and the nanostructures 55 from undesired nitrogen diffusion during the annealing process. Further, the second liner layer 68B may protect the overlying STI material 68C from undue etching in subsequent processes (e.g., processes to remove the nanostructures 52 and/or 54). It has been observed that by forming the second liner layer 68B to have an atomic percentage of nitrogen in the range of 4% to 13%, described above, the second liner layer 68B can be easily formed while also providing sufficiently high-etch selectivity to prevent undue etching of the STI material 68C in subsequent processing steps. As a result, manufacturing defects in the resulting transistor devices can be reduced and electrical performance can be improved.

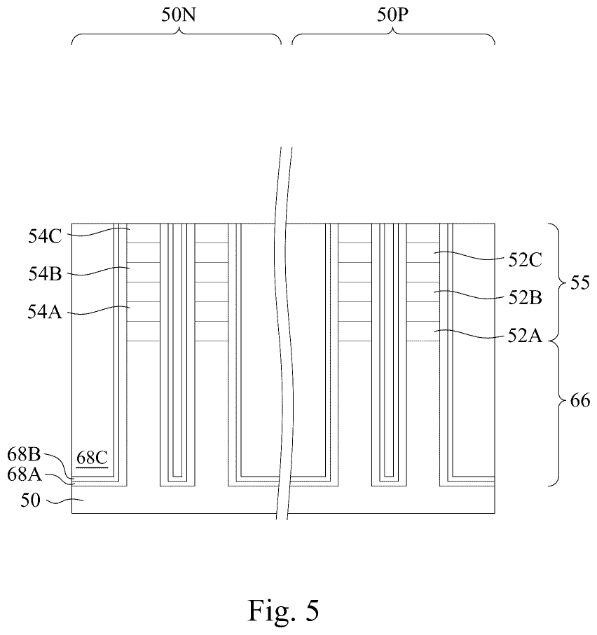

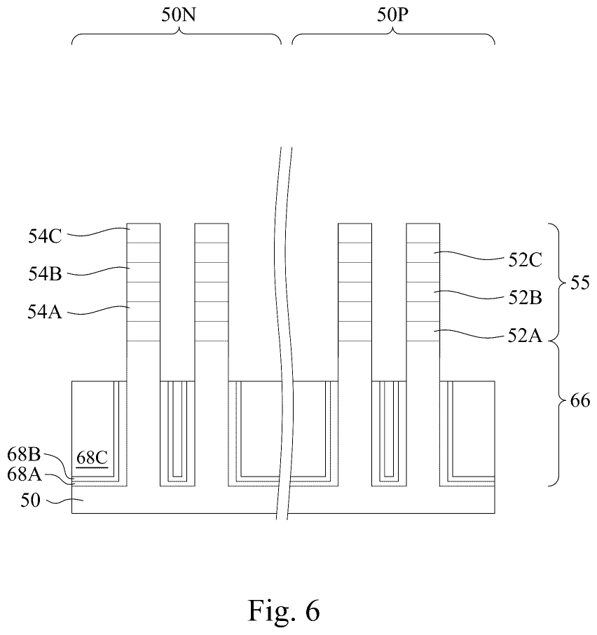

In FIGS. 5 and 6, a removal process is then applied to the first liner layer 68A, the second liner layer 68B, and the STI material 68C to remove excess insulation material over the nanostructures 55. In some embodiments, a planarization process such as a chemical mechanical polish (CMP), an etch-back process, combinations thereof, or the like may be utilized as illustrated by FIG. 5. The planarization process may also remove the hard masks 56 and expose the nanostructures 55 such that top surfaces of the nanostructures 55, the first liner layer 68A, the second liner layer 68B, and the STI material 68C are level after the planarization process is complete.

Then, in FIG. 6, the first liner layer 68A, the second liner layer 68B, and the STI material 68C are recessed below the nanostructures 55. The first liner layer 68A, the second liner layer 68B, and the STI material 68C are recessed such that upper portions of fins 66 in the n-type region 50N and the p-type region 50P protrude from top surfaces of the first liner layer 68A, the second liner layer 68B, and the STI material 68C. Further, the top surfaces of the first liner layer 68A, the second liner layer 68B, and the STI material 68C may have a flat surface as illustrated, a convex surface, a concave surface (such as dishing), or a combination thereof. The top surfaces of the first liner layer 68A, the second liner layer 68B, and the STI material 68C may be formed flat, convex, and/or concave by an appropriate etch. The first liner layer 68A, the second liner layer 68B, and the STI material 68C may be recessed using one or more acceptable etching processes, such as ones that are selective to the material of the first liner layer 68A, the second liner layer 68B, and the STI material 68C (e.g., etches the material of the insulation materials of the of the first liner layer 68A, the second liner layer 68B, and the STI material 68C at a faster rate than the material of the fins 66 and the nanostructures 55). After the recessing, the STI material 68C may be referred to as STI regions 68C.

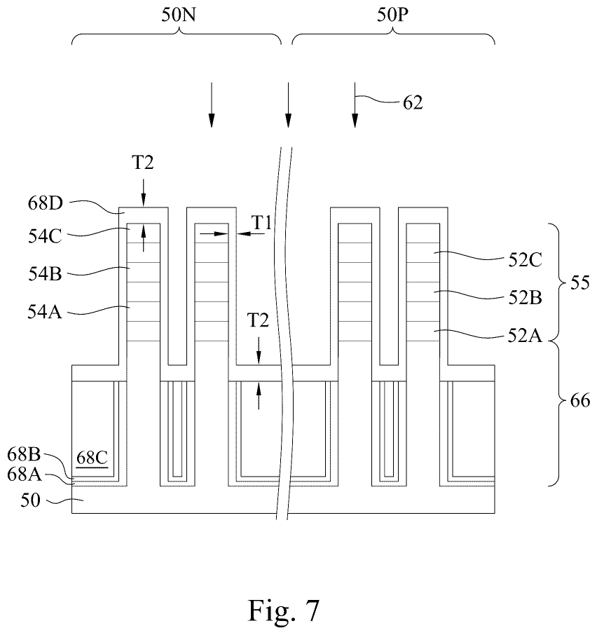

In FIG. 7, a third liner layer 68D is deposited over and along sidewalls of the fins 66 and the nanostructures 55 and further deposited over top surfaces of the inner STI regions 68C, the first liner layer 68A, and the second liner layer 68B. The third liner layer 68D may be a nitride layer, such as a silicon nitride layer, a silicon oxynitride layer, a silicon oxycarbonitride layer, or the like. In a specific embodiment, the third liner layer 68D is a SiN layer with an atomic percentage of silicon in a range of 62% to 72% and an atomic percentage of nitrogen in a range of 28% to 38%. For example, the third liner layer 68D may comprise 67 at % silicon and 33 at % nitrogen.

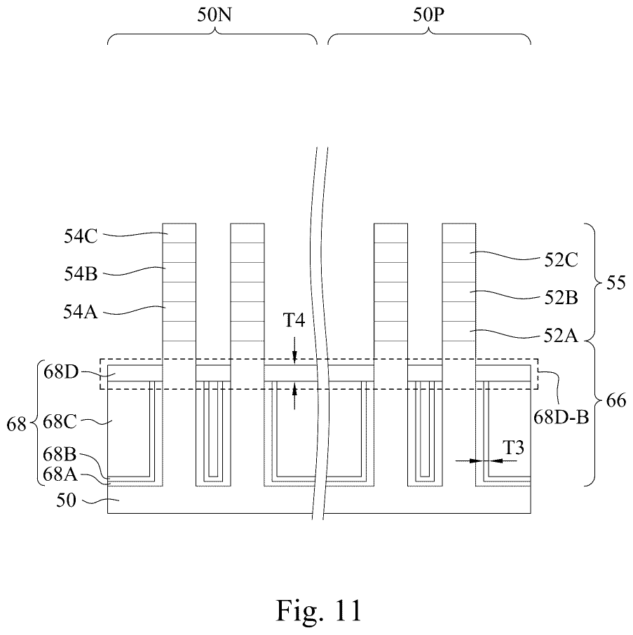

In some embodiments, the third liner layer 68D is deposited by a non-conformal deposition process, such as, a plasma enhanced CVD (PECVD) process or the like. The non-conformal deposition process may form sidewalls portions of the third liner layer 68D to have a thickness T1 that is less a thickness T2 of lateral portions of third liner layer 68D. The non- conformal deposition process may aid in the patterning and selective removal of the sidewall portions of the third liner layer 68D as will be discussed in greater detail subsequently. In some embodiments, a ratio of the thickness T1 to the thickness T2 may be in the range of 0.15 to 0.23. It has been observed that when the ratio of the thicknesses T1 and T2 is in the above range, portions of the third liner layer 68D can be selectively removed to achieve the desired isolation structure 68 (see FIG. 11) without unduly complicating the fabrication process.

In some embodiments, the non-conformal deposition process is a PECVD process. The PECVD process may be performed at a temperature in a range of 400° C. to 500° C. During the PECVD process, a silicon-based precursor and H2 gas may be flowed into the chamber to form a silicon-based material layer (e.g., a silicon layer) over and along sidewalls of the fins 66 and the nanostructures 55. The silicon-based precursor flowed to form the third liner layer 68D may have a same or different chemical composition as the silicon-based precursor flowed to form the second liner layer 68B. Subsequently to or concurrently with depositing silicon-based material layer, a plasma treatment may be applied to treat the silicon-based material layer with a nitrogen-containing radical, thereby forming the third liner layer 68D. The plasma treatment may be applied in a direction that is substantially perpendicular to a top surface of the substrate 50 as indicated by the arrows 62. The directionality of the plasma treatment results in the difference of thicknesses T1 and T2 between the sidewall portions and the lateral portions of the third liner layer 68D, respectively. Further, the directionality of the plasma treatment may result in an improved quality film (e.g., increased nitrogen uniformity) in the lateral portions of the third liner layer 68D compared to the sidewall portions of the third liner layer 68D.

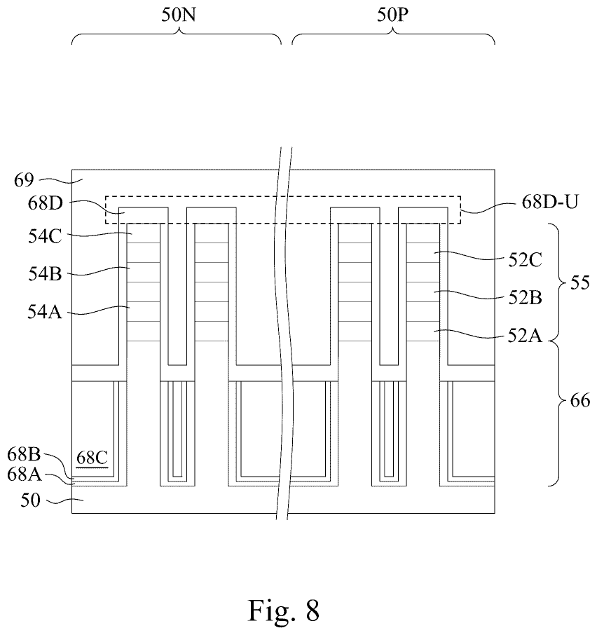

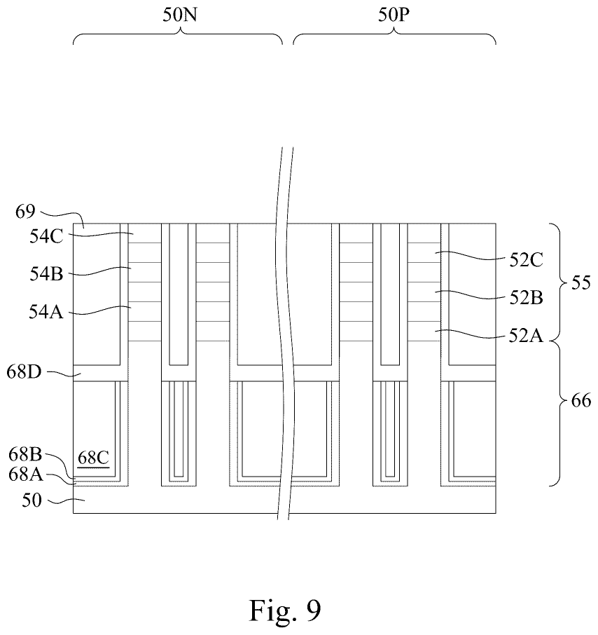

In FIGS. 8 and 9, upper portions 68D-U of the third liner layer 68D are removed. The upper portions 68D-U of the third liner layer 68D may include lateral portions of the third liner layer 68D that are disposed above the nanostructures 55. Removing the upper portions 68D-U of the third liner layer 68D may include depositing a mask layer 69 over the third liner layer 68D as illustrated by FIG. 8. The mask layer 69 may extend over the nanostructures 55. In some embodiments, the mask layer 69 is a backside anti-reflective coating (BARC) layer that is deposited by PVD or the like. Other materials and/or deposition processes are possible in other embodiments.

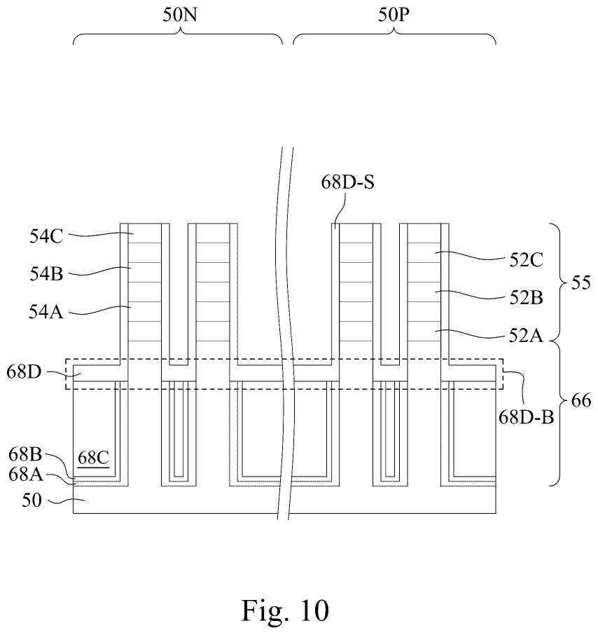

Subsequently, in FIG. 9, one or more etching processes may be performed to remove the upper portions 68D-U of the third liner layer 68D. For example, an etch back process may be applied to the mask layer 69 to expose the upper portions 68D-U of the third liner layer 68D. Then, the upper portions 68D-U of the third liner layer 68D may be etched away by an anisotropic etching process, for example. In some embodiments, the anisotropic etching process is a dry etch using H₃PO₄, H₃PO₅, p33, or the like as an etchant. Remaining portions of the mask layer 69 protects sidewall and bottom portions of the third liner layer 68D while the upper portions 68D-U of the third liner layer 68D are removed. After the upper portions 68D-U are removed, the remaining mask layer 69 may also be removed using a suitable etching and/or cleaning process. The resulting structure is illustrated in FIG. 10.

In FIG. 11, sidewall portions 68D-S (see FIG. 10) are then removed from the sidewalls of the nanostructures 55 and the fins 66 while bottom portions 68D-B remain on the top surfaces of the inner STI regions 68C. Removing the sidewall portions 68D-S may include an etching process, such as an isotropic etching process. Some embodiments, the isotropic etching process is a wet etch using HPO₃ or the like as an etchant. As discussed above, the sidewall portions 68D-S are formed to be thinner than the bottom portions 68D-B as a result of the non-conformal deposition process (e.g., PECVD) used to deposit the third liner layer 68D. For example, a ratio of the thickness T1 of the sidewall portions 68D-S to the thickness T2 of the bottom portions 68D-B may be in a range of 0.15 to 0.23 (see FIG. 7). The relative thinness of the sidewall portions 68D-S compared to the bottom portions 68D-B allow for the sidewall portions 68D-S to be completely removed prior to completely removing the bottom portions 68D-B when an isotropic etching process is applied. As a result, the non-conformal deposition process described above allows the third liner layer 68D to be selectively etched away from the sidewalls of the nanostructures 55 and the fins 66 while still leaving the bottom, lateral portions of the third liner layer 68D to cover the inner STI regions 68C.

After the sidewall portions 68D-S are removed, the remaining third liner layer 68D may also be referred to as an STI hard mask 68D. Thus, an isolation structure 68 is formed. The isolation structure 68 includes the first liner layer 68A, the second liner layer 68B, the inner STI region 68C, and the STI hard mask 68D. The second liner layer 68B and the STI hard mask 68D are made of materials that protect the inner STI region 68C during subsequent processing steps (e.g., subsequent etching and/or cleaning processes). Specifically, the second liner layer 68B protects a bottom surface and sidewalls of the inner STI region 68C, and the STI hard mask 68D protects an upper surface of the STI region 68C. In this manner, the second liner layer 68B and the STI hard mask 68D, in combination, may completely surround and encapsulate the STI region 68C to protect the inner STI region 68C from being exposed to etchants of subsequent etching/cleaning processes.

The material(s) of the second liner layer 68B and the STI hard mask 68D may be selected to have high-etch selectivity to the material of the inner STI region 68C relative a same etching process. For example, the material(s) of the second liner layer 68B and the STI hard mask 68D may be selected to be resistant to etchants that etch the material of the inner STI region 68C. For example, one or more etchants may etch the material(s) of the second liner layer 68B and the STI hard mask 68D at least ten times slower than a material of the inner STI region 68C. In some embodiments, the second liner layer 68B and the STI hard mask 68D are made of nitrides with the nitrogen percentages described above when the inner STI region 68C is an oxide. The nitrogen concentrations of the second liner layer 68B and the STI hard mask 68D may each be higher than a nitrogen concentration of the inner STI region 68C. It has been observed that when the second liner layer 68B has an atomic percentage of nitrogen in a range of 4% to 13% and the STI hard mask 68D has an atomic percentage of nitrogen in a range of 28% to 38%, each described above, the second liner layer 68B and the STI hard mask 68D can be easily formed while also providing sufficient etch selectivity to prevent undue etching of the STI region 68C in subsequent processing steps. As a result, undue loss of the inner STI region 68C can be avoided, manufacturing defects can be reduced, and device performance can improve. In some embodiments, the nitrogen concentration of the STI hard mask 68D is greater than a nitrogen concentration of the second liner layer 68B because the STI hard mask 68D will have greater exposure to etchants in subsequent processing steps. As a result, having a higher nitrogen concentration in the STI hard mask 68D, improves its ability to withstand etching and improves protection to the underlying inner STI region 68C.

The second liner layer 68B and the STI hard mask 68D may have a thickness T3 and T4, respectively, which are each at least 2 nm. It has been observed that when the thicknesses T3 and T4 are less than 2 nm, the inner STI regions 68C are not adequately protected, and an unacceptably high degree of etching the inner STI regions 68C occurs in subsequent processing. The thickness T3 of the second liner layer 68B may be less than, equal to, or greater than the thickness T4 of the STI hard mask 68D. In some specific embodiments, the thickness T4 of the STI hard mask 68D may be in a range of 5 nm to 10 nm.

Further in FIG. 11, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 101³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

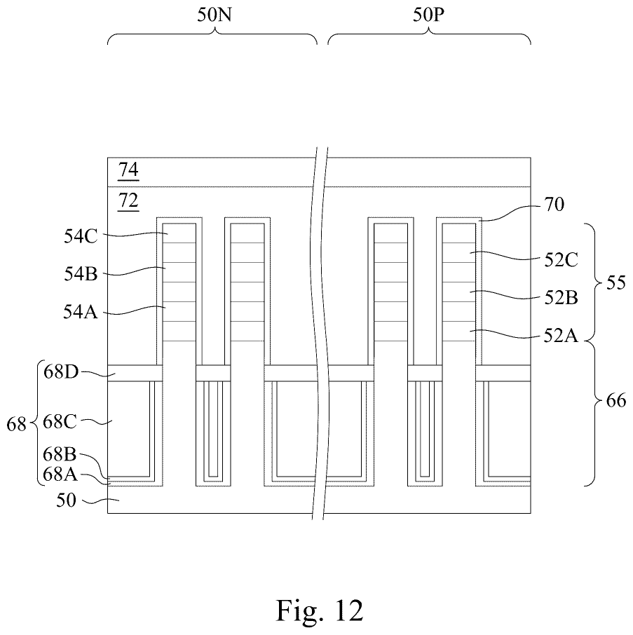

In FIG. 12, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the isolation structures 68, such that the dummy dielectric layer 70 extends between the dummy gate layer 72 and the isolation structures 68.

FIGS. 13A through 27C illustrate various additional steps in the manufacturing of embodiment devices. FIGS. 14A, 15A, 16A, 17A, 18A, 19A, 19C, 20A, 20C, 21A, 22A, 23C, 25C, 26C, and 27C illustrate features in either the regions 50N or the regions 50P, and FIGS. 13A, 13B, 14B, 15B, 16B, 17B, 18B, 18C, 19B, 19D, 20B, 21B, 22B, 23A, 23B, 24A, 24B, 25A, 25B, 26A, 26B, 27A, and 27B illustrate features in both the regions 50N and the regions 50P. In FIGS. 13A and 13B, the mask layer 74 (see FIG. 12) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 14A and 14B, a first spacer layer 80 and a second spacer layer 82 are formed over the structures illustrated in FIGS. 13A and 13B, respectively. The first spacer layer 80 and the second spacer layer 82 will be subsequently patterned to act as spacers for forming self-aligned source/drain regions. In FIGS. 14A and 14B, the first spacer layer 80 is formed on top surfaces of the isolation structures 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 11, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

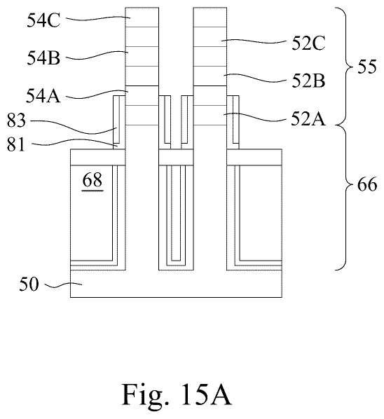

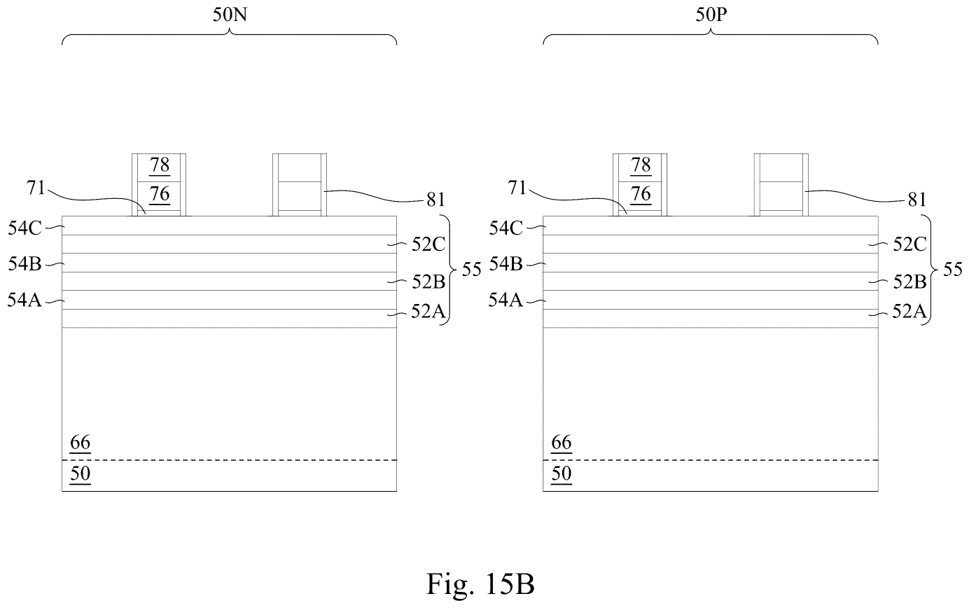

In FIGS. 15A and 15B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 15A. Thereafter, the second spacers 83 acts as a mask while etching exposed portions of the first spacer layer 80, thereby forming first spacers 81 as illustrated in FIG. 15A.

As illustrated in FIG. 15A, the first spacers 81 and the second spacers 83 are disposed on sidewalls of the fins 66 and/or nanostructures 55. As illustrated in FIG. 15B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

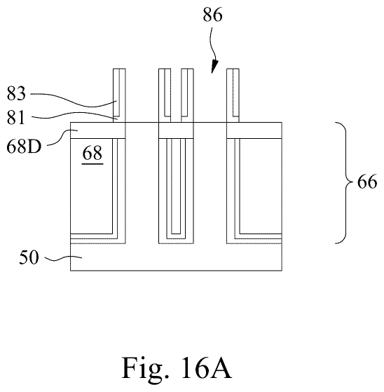

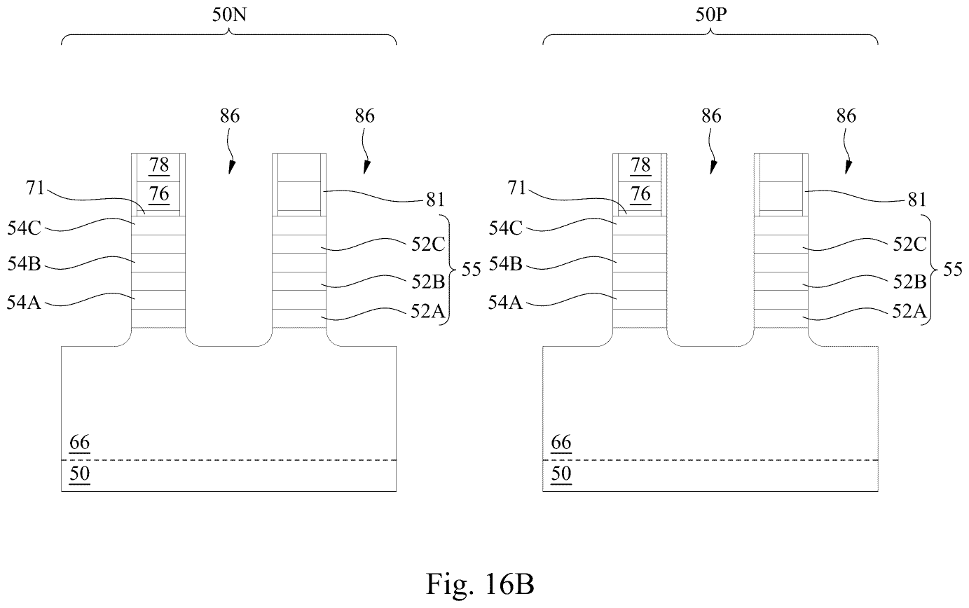

In FIGS. 16A and 16B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 16A, top surfaces of the isolation structures 68 (e.g., a top surface of the STI hard mask 68D) may be level with bottom surfaces of the first recesses 86. In various embodiments, the fins 66 may be etched such that bottom surfaces of the first recesses 86 are disposed below the top surfaces of the isolation structures 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

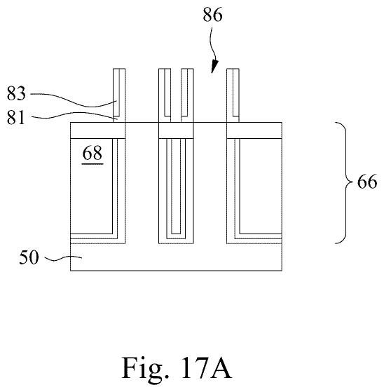

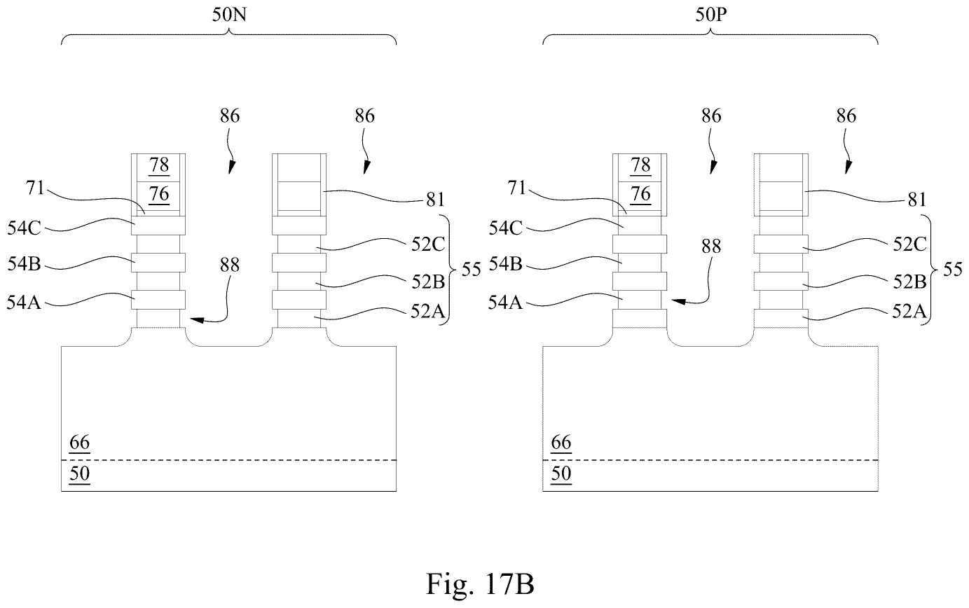

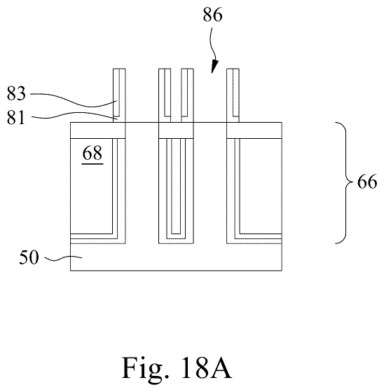

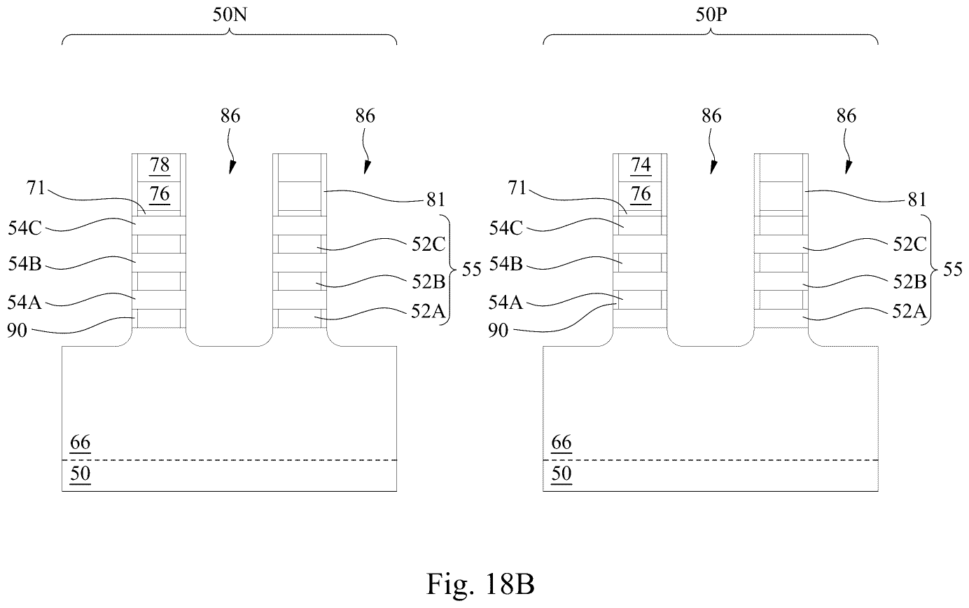

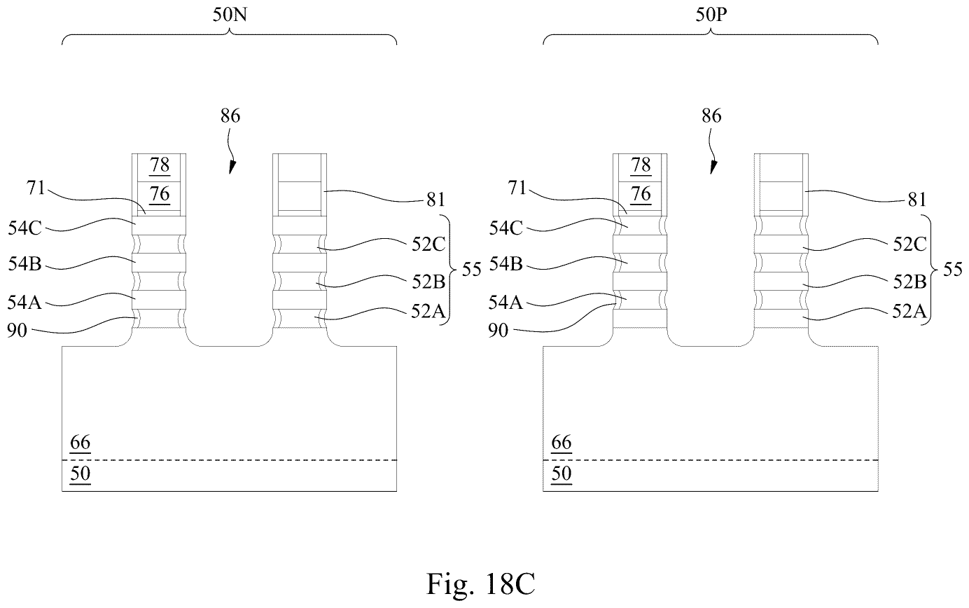

In FIGS. 17A and 17B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 64 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 17B, the sidewalls may be concave or convex (see e.g., FIG. 18C). The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

In FIGS. 18A-18C, first inner spacers 90 are formed in the sidewall recesses 88. The first inner spacers 90 may be formed by depositing an inner spacer layer (not separately illustrated) over the structures illustrated in FIGS. 17A and 17B. The first inner spacers 90 act as isolation features between subsequently formed source/drain regions and a gate structure. As will be discussed in greater detail below, source/drain regions will be formed in the recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

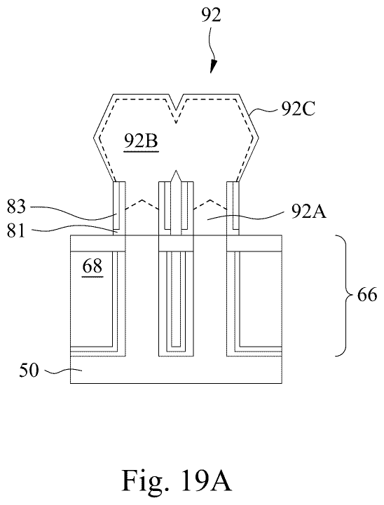

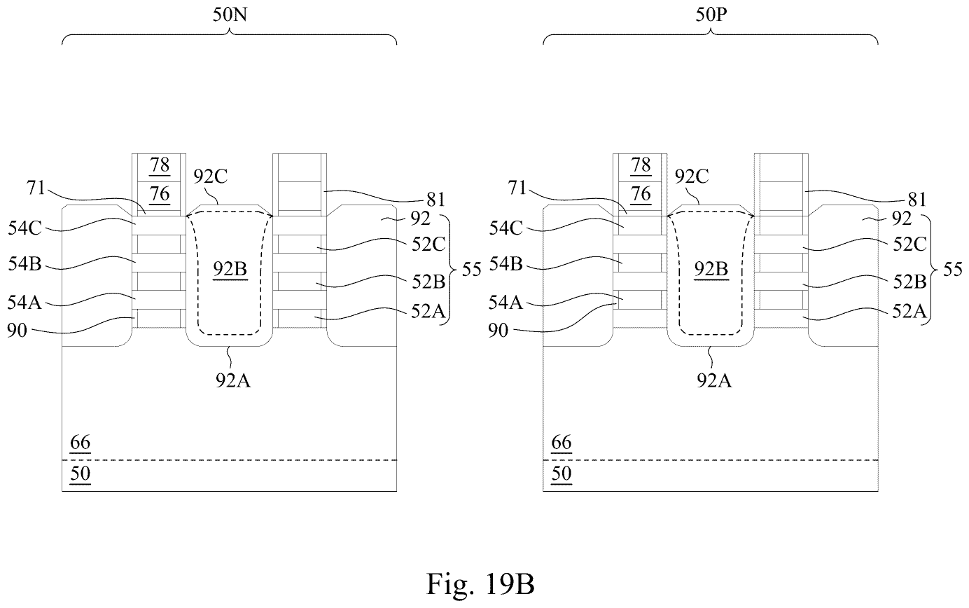

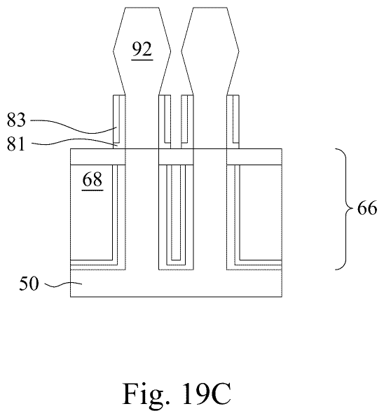

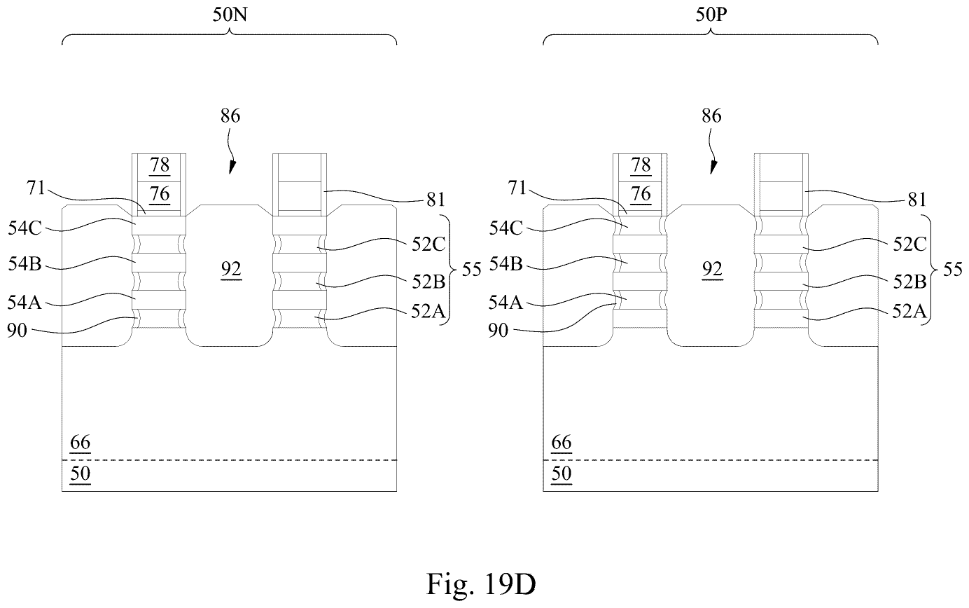

Moreover, although the outer sidewalls of the first inner spacers 90 are illustrated as being straight in FIG. 18B, the outer sidewalls of the first inner spacers 90 may be concave or convex. As an example, FIG. 18C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 19A-19C) by subsequent etching processes, such as etching processes used to form gate structures.

In FIGS. 19A-19C, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 19B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 19A. In other embodiments, adjacent epitaxial source/drain regions 92 remain separated after the epitaxy process is completed as illustrated by FIG. 19C. In the embodiments illustrated in FIGS. 19A and 19C, the first spacers 81 may be formed to a top surface of the isolation structures 68, thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 19D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 19D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

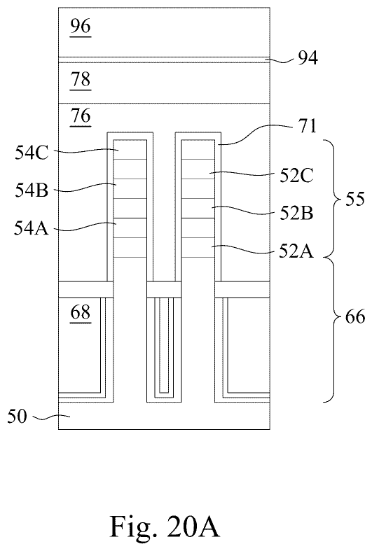

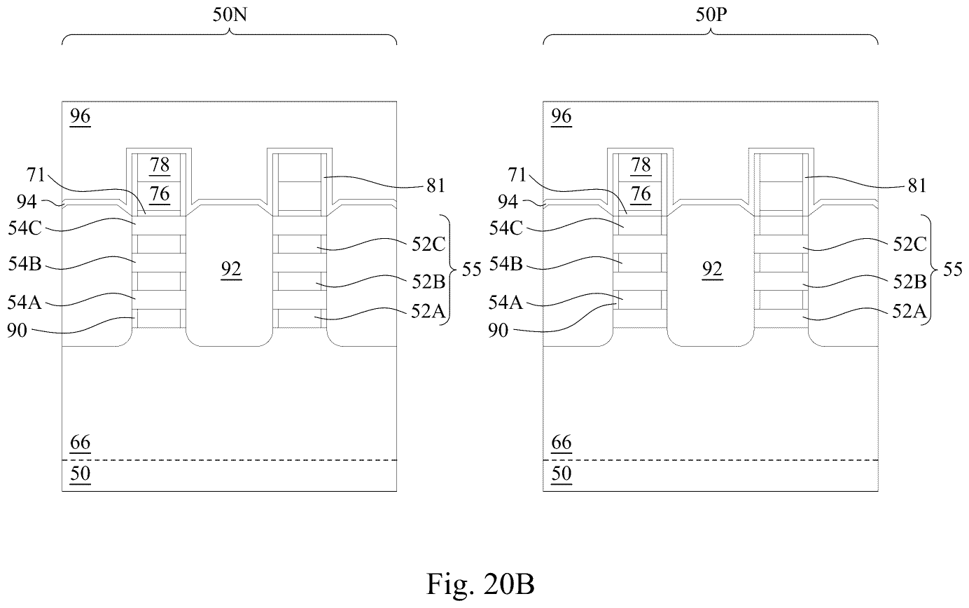

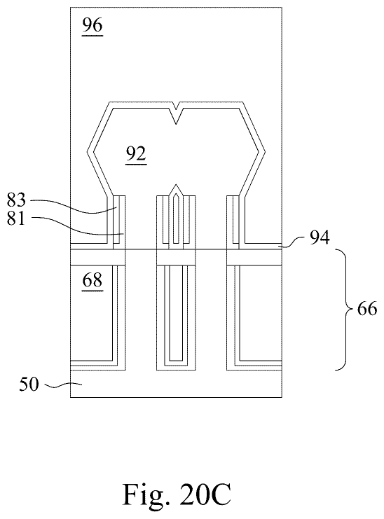

In FIGS. 20A-20C, a first interlayer dielectric (ILD) 96 is deposited over the structure illustrated in FIGS. 13A, 19B, and 19A, respectively. It is noted that the processes of FIGS. 14A-19D do not substantially alter the cross-section illustrated in FIGS. 13A. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

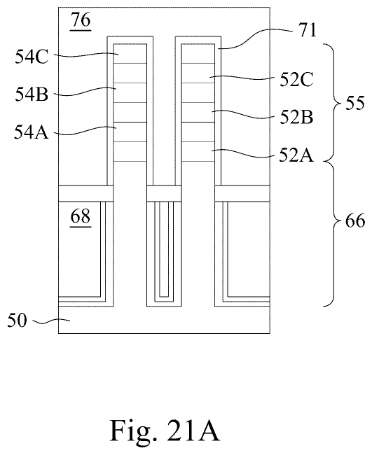

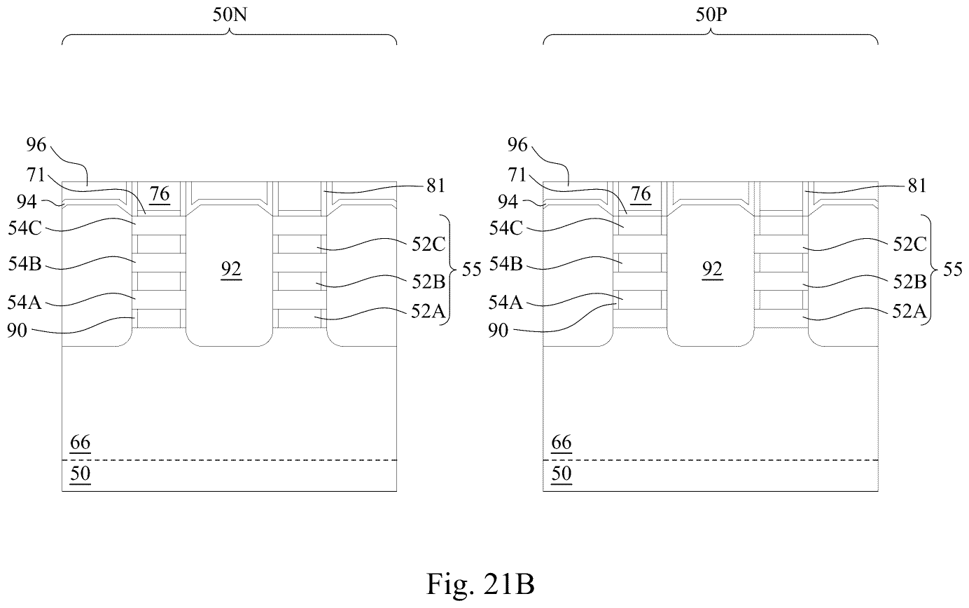

In FIGS. 21A and 21B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 72 are exposed through the first ILD 96. In some embodiments, the masks 78 may remain, in which case the planarization process levels the top surface of the first ILD 96 with top surface of the masks 78 and the first spacers 81.

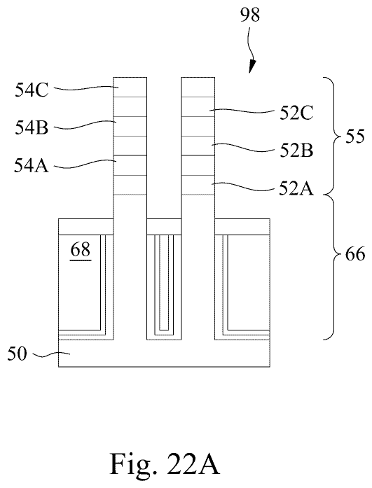

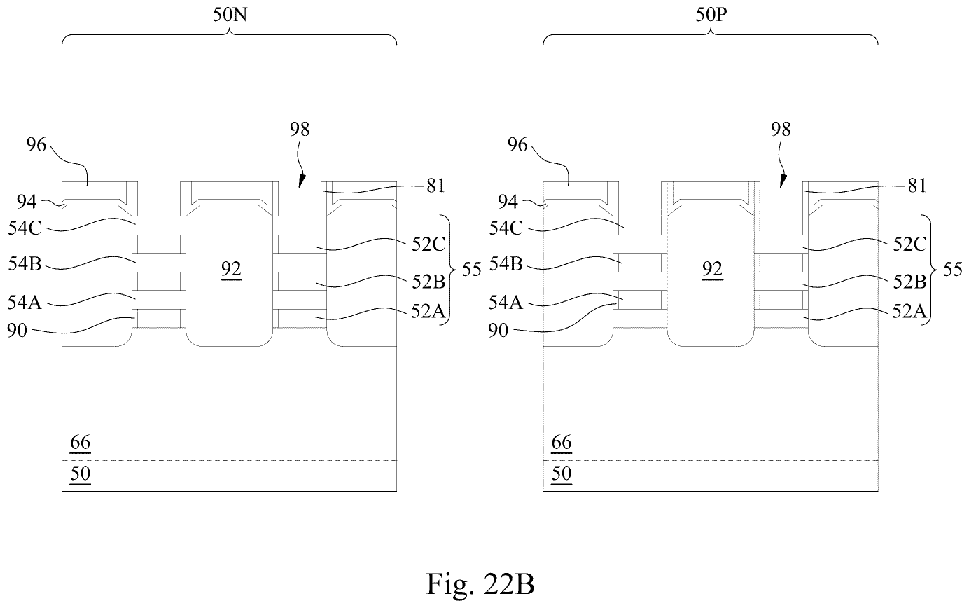

In FIGS. 22A and 22B, the dummy gates 76, and the masks 78 if present, are removed in one or more etching steps, so that second recesses 98 are formed. Portions of the dummy gate dielectrics 71 in the second recesses 98 are also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

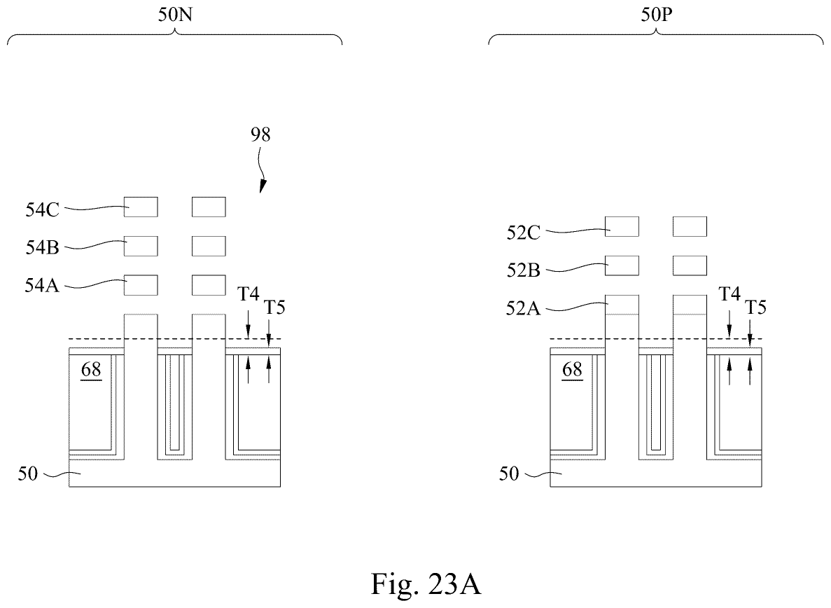

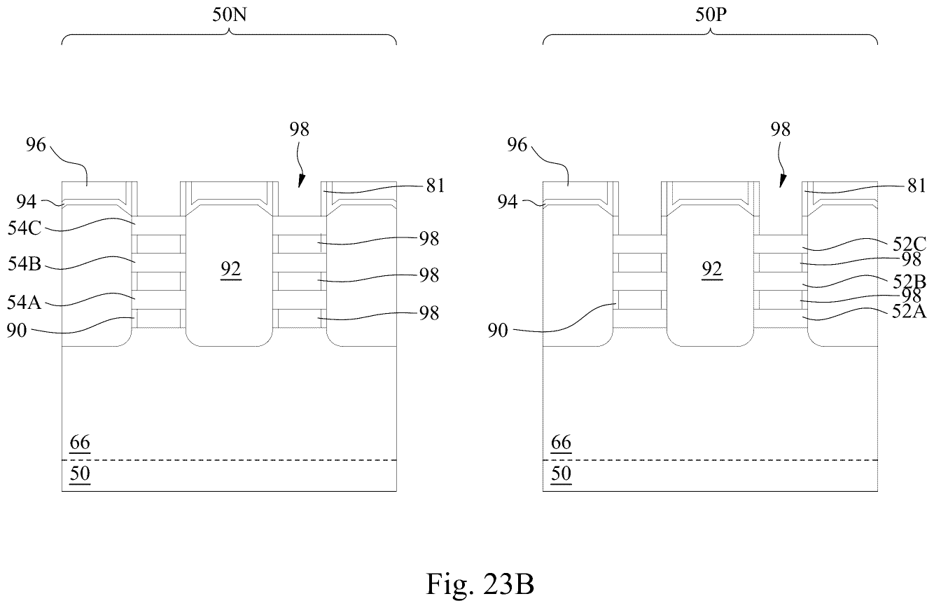

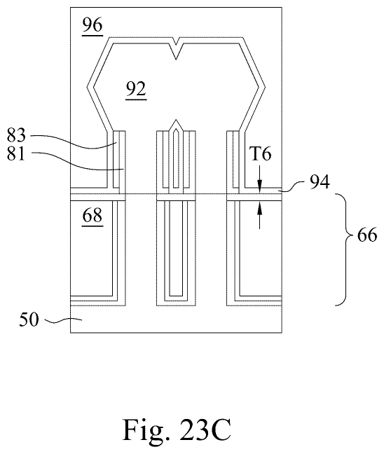

In FIGS. 23A-23C, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, and the STI structures 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, and the STI structures 68 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 28A, 28B, and 28C illustrate a structure resulting from such embodiments where the channel regions in both the p-type region 50P and the n-type region 50N are provided by the second nanostructures 54 and comprise silicon, for example.

In various embodiments, the STI structures 68 in both the n-type region 50N and the p-type region 50P are relatively unetched due to the STI hard mask 68D and the second liner layer 68B providing increased etch resistivity to the inner STI region 68C. For example, in the process steps described above in FIGS. 12 through 23C, the STI structures 68 may be exposed to one or more etchants that etches the inner STI region 68C at a greater rate (e.g., at least 10 times greater) than each of the STI hard mask 68D and the second liner layer 68B. While the etchants may still reduce an overall thickness of the STI structures 68, STI loss kept at an acceptably low amount. For example, a thickness of the STI hard mask 68D may be reduced from its original thickness T4 (see also FIG. 11) to a thickness T5. Loss of the STI hard mask 68D (e.g., the difference between the thicknesses T4 and T5) may be less than 5 nm in some embodiments, thereby leaving adequate isolation in the resulting transistors devices and improving device performance. In some embodiments, the original thickness T4 of the STI hard mask 68D may be in a range of 5 nm to 10 nm, and the thickness T5 of the STI hard mask 68D after additional processing may be in a range of 2 nm to 5 nm. Further, as illustrated by FIG. 23C, portions of the STI hard mask 68D may be covered by the CESL 94 and the first ILD 96 during some of the processing described above (e.g., during the removal of the dummy gates 76, the dummy gate dielectrics 71, and select nanostructures 55). As such, these covered portions of the STI hard mask 68D that directly underlie the first ILD 96 may be etched less than exposed portions of the STI hard mask 68D (see FIG. 23A). For example, the covered portions of the STI hard mask 68D may have a thickness T6 (see FIG. 23C) that is different from the thickness T5 of the exposed portions of the STI hard mask 68D (see FIG. 23A). In some embodiments, the thickness T6 may be greater than the thickness T5. In some embodiments, the thickness T6 may also be less than the original thickness T4.

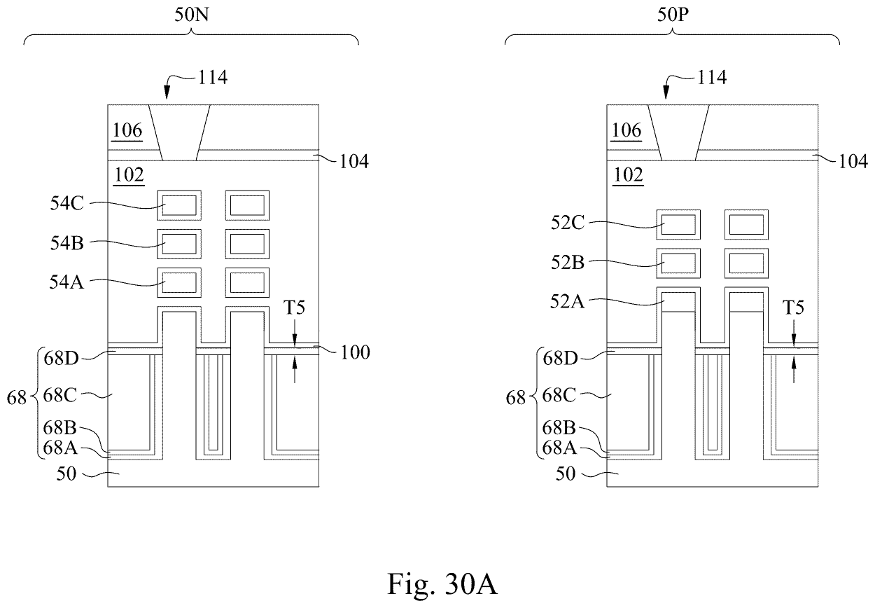

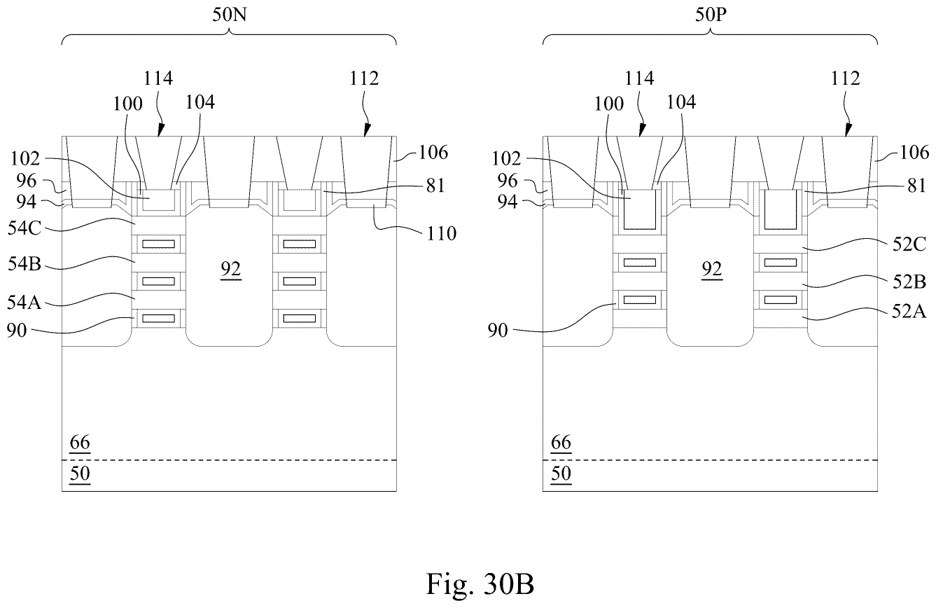

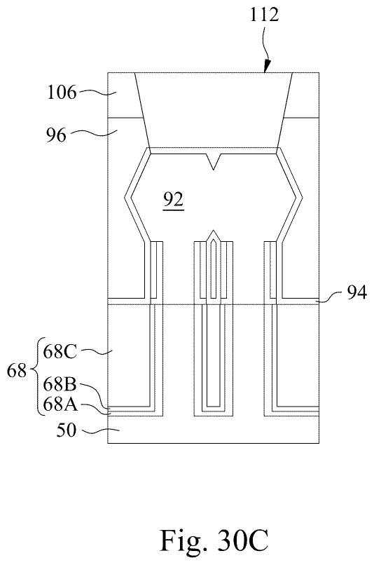

In other embodiments, the thickness T6 may be less than the thickness T5. For example, the thickness T6 may be zero in embodiments where portions of the STI hard mask 68D outside the dummy gates 76 are removed during previous processing steps. For example, during dummy gate patterning steps, the STI hard mask 68D may be completely removed except for areas directly covered by the dummy gates 76. In such embodiments, the STI hard mask 68D may not be formed directly under the first ILD 96. FIGS. 30A-30C illustrate such an embodiment.

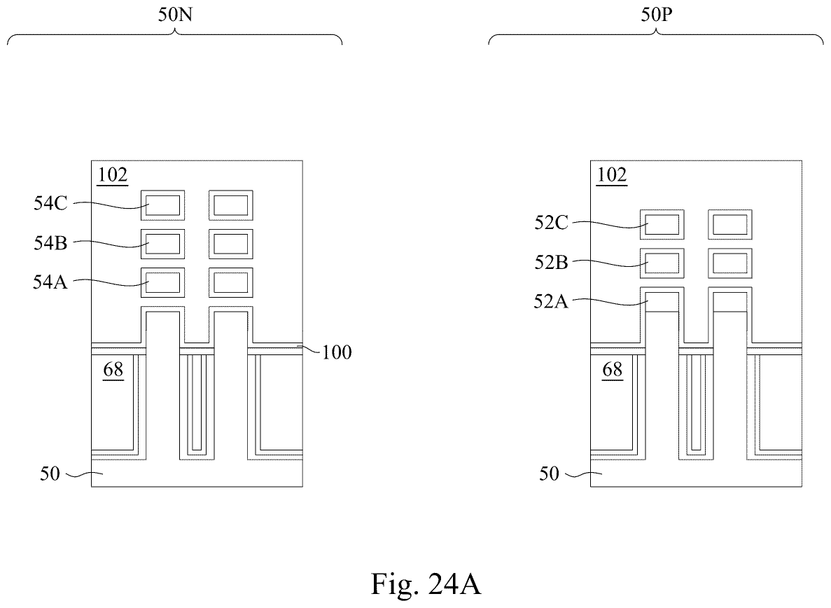

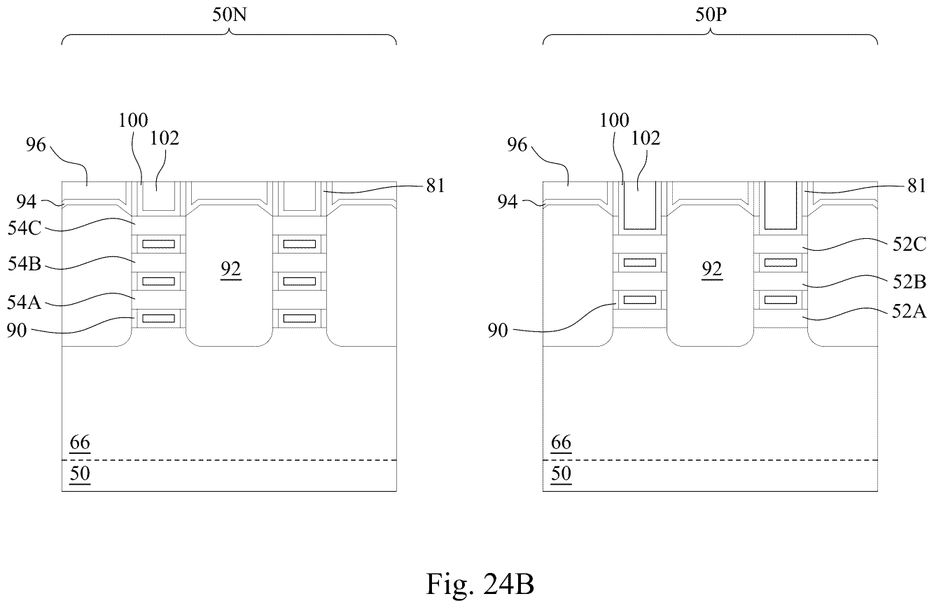

In FIGS. 24A and 24B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI structures 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 24A and 24B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p- type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

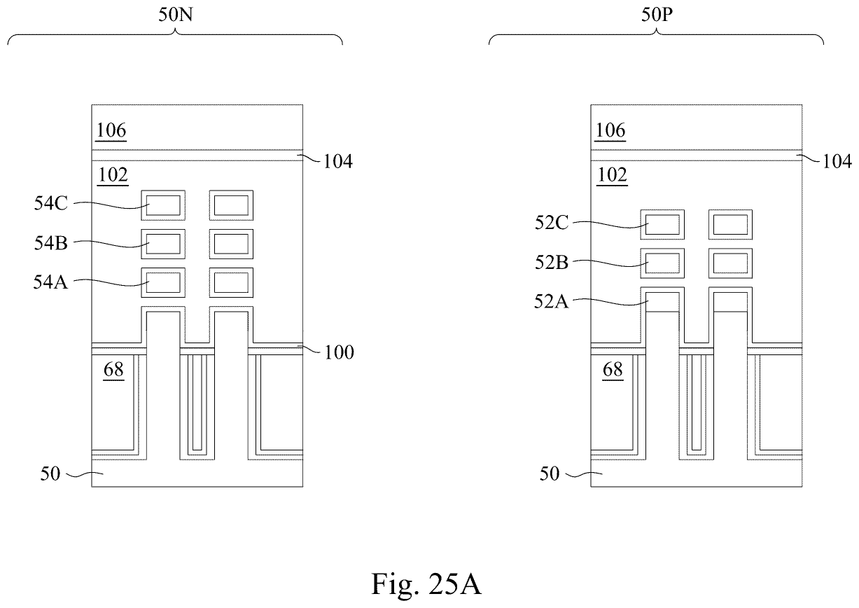

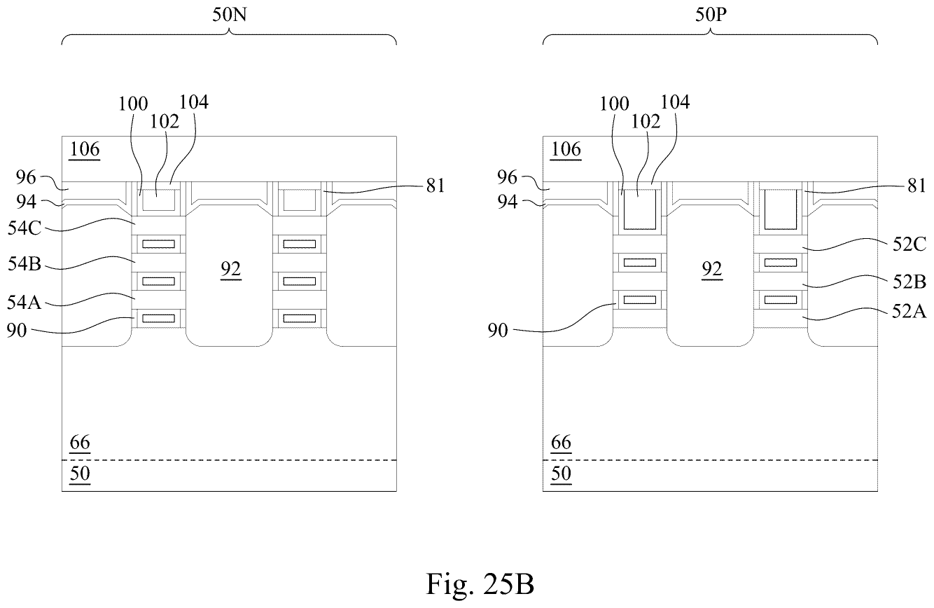

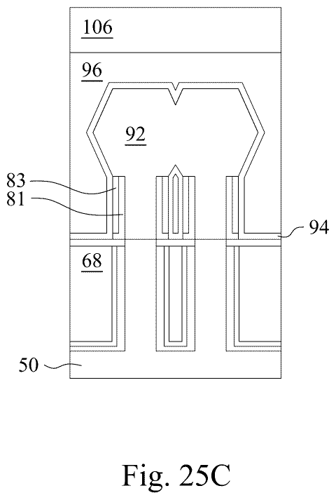

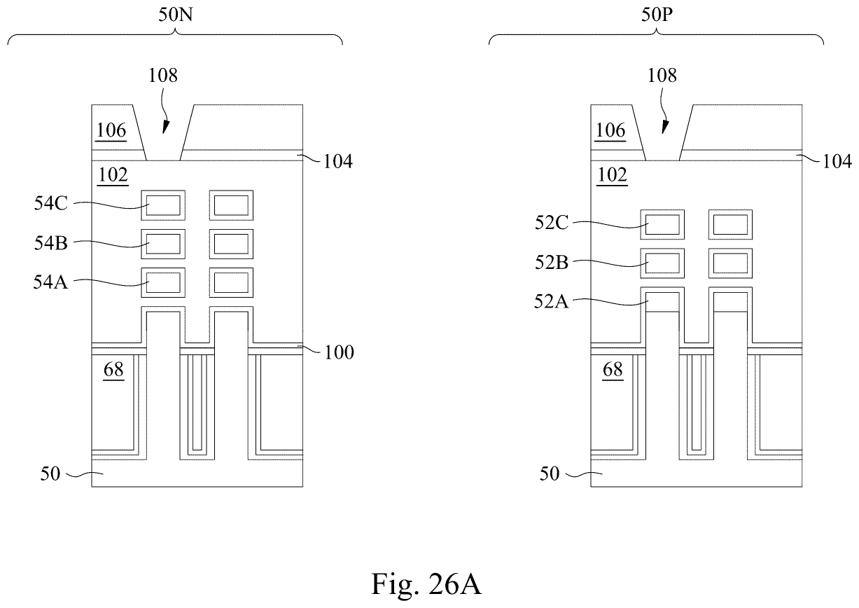

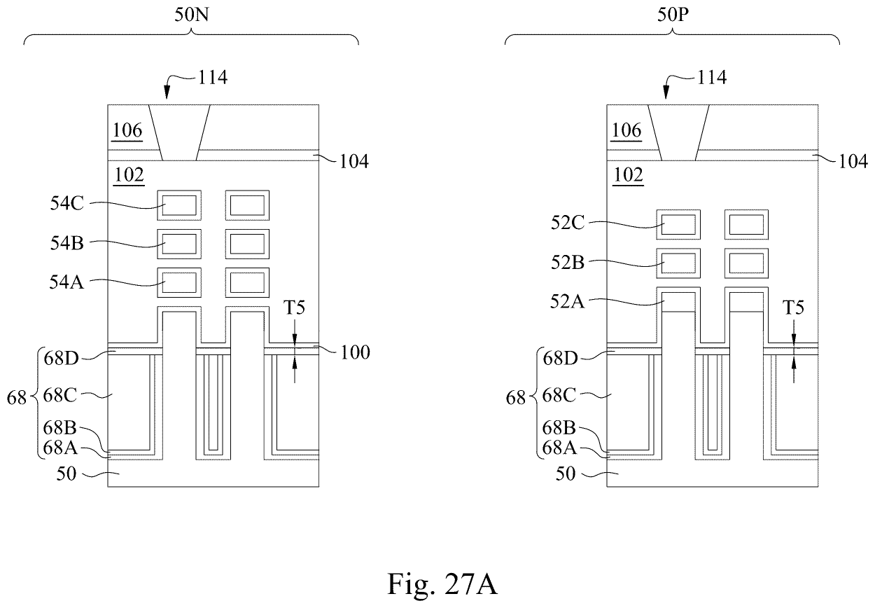

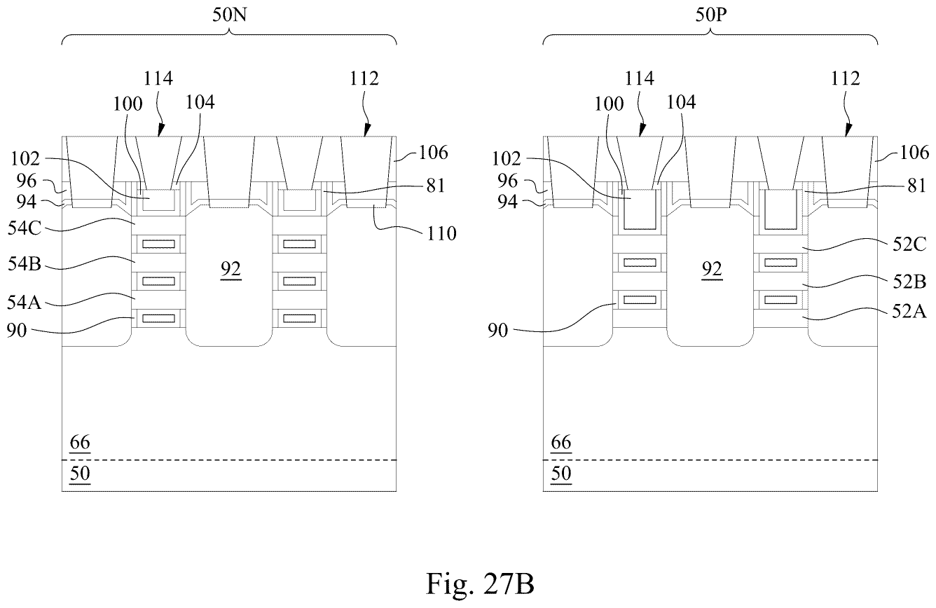

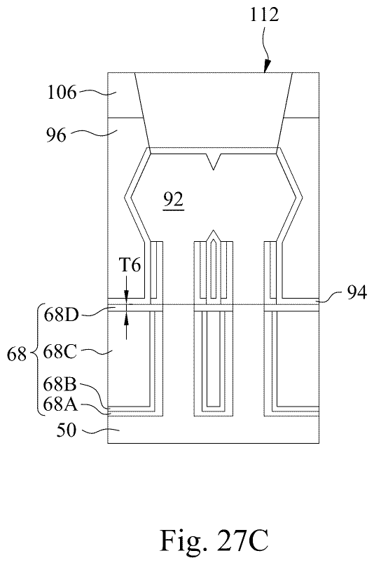

In FIGS. 25A-25C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 27A and 27B) penetrate through the gate mask 104 to contact the top surface of the recessed gate electrodes 102.

As further illustrated by FIGS. 25A-25C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

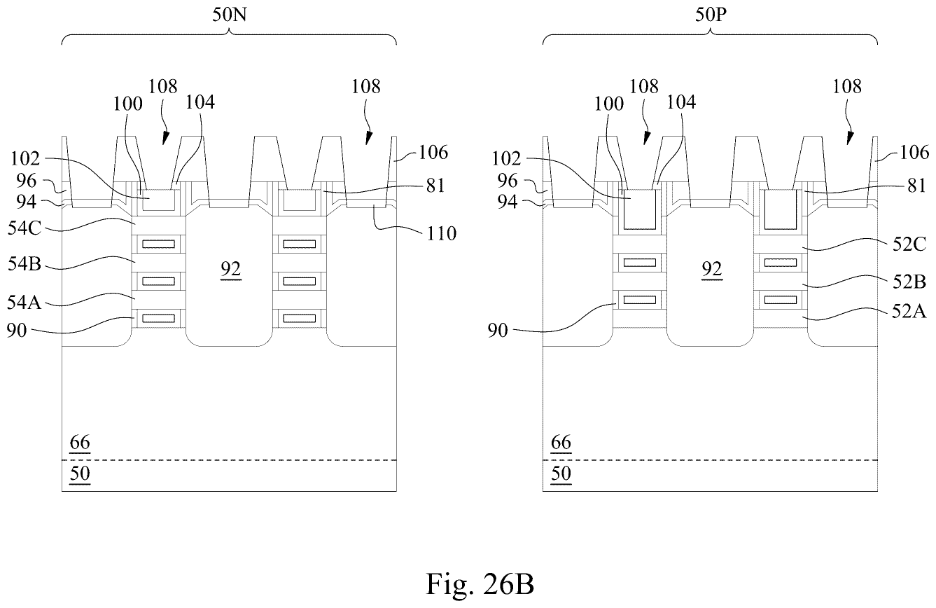

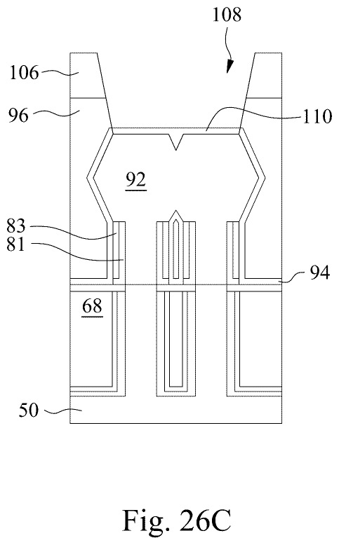

In FIGS. 26A-26C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 26B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 27A-27C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 28A-28C illustrate cross-sectional views of a device according to some alternative embodiments. FIGS. 28A illustrates reference cross-section A-A′ illustrated in FIG. 1. FIG. 28B illustrates reference cross-section B-B′ illustrated in FIG. 1. FIG. 28C illustrates reference cross-section C-C′ illustrated in FIG. 1. In FIGS. 28A-28C, like reference numerals indicate like elements formed by like processes as the structure of FIGS. 27A-27C. For example, the structures of FIGS. 28A-28C includes isolation structures 68 comprising an inner STI region 68C that is surrounded by a second liner layer 68B and an STI hard mask 68D. The STI hard mask 68D may have thicknesses T5 (see FIG. 28A) and T6 (see FIG. 28C) as described above. However, in FIGS. 28A-28C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. The structure of FIGS. 28A-28C may be formed, for example, by removing the first nanostructures 52 from both the p-type region 50P and the n-type region 50N simultaneously; depositing the gate dielectric layers 100 and the gate electrodes 102P (e.g., gate electrode suitable for a p-type nano-FET) around the second nanostructures 54 in the p-type region 50P; and depositing the gate dielectric layers 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

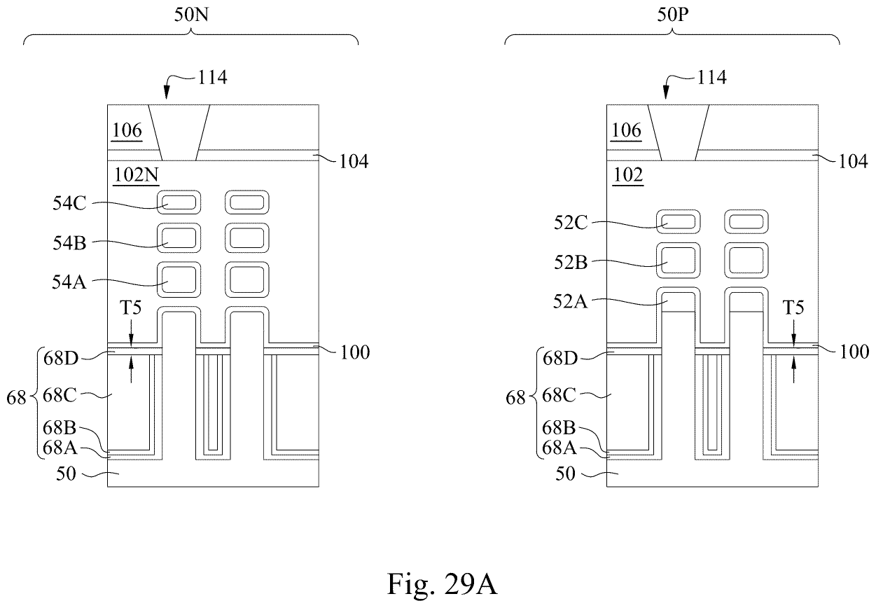

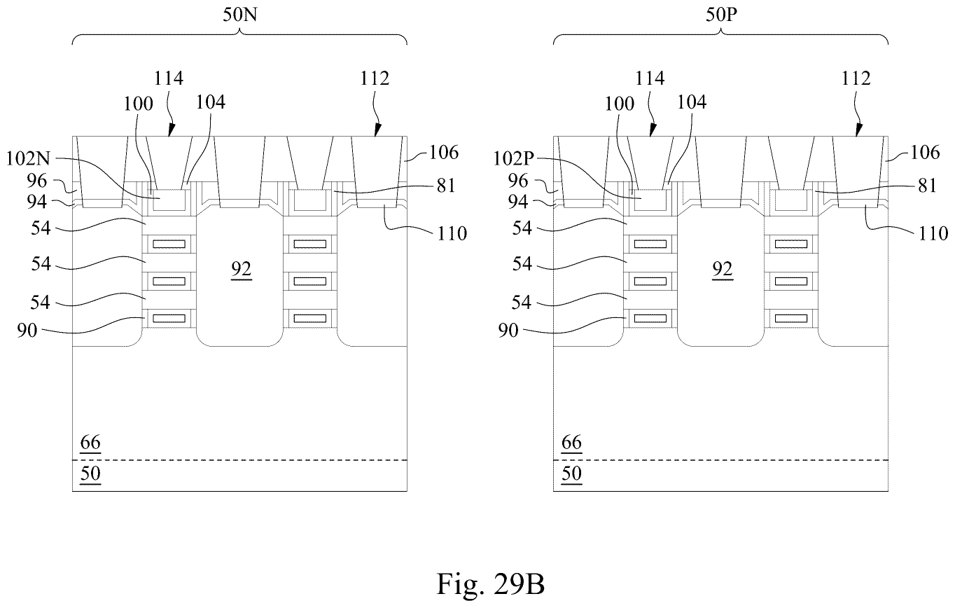

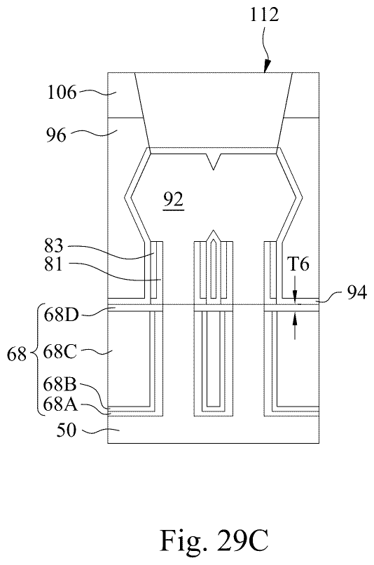

FIGS. 29A-29C illustrate cross-sectional views of a device according to some alternative embodiments. FIGS. 29A illustrates reference cross-section A-A′ illustrated in FIG. 1. FIG. 29B illustrates reference cross-section B-B′ illustrated in FIG. 1. FIG. 29C illustrates reference cross-section C-C′ illustrated in FIG. 1. In FIGS. 29A-29C, like reference numerals indicate like elements formed by like processes as the structure of FIGS. 27A-27C. For example, the structures of FIGS. 29A-29C includes isolation structures 68 comprising an inner STI region 68C that is surrounded by a second liner layer 68B and an STI hard mask 68D. The STI hard mask 68D may have thicknesses T5 (see FIG. 29A) and T6 (see FIG. 29C) as described above. However, in FIGS. 29A-29C, channel regions 54 in the n-type region 50N and channel regions 52 the p-type region 50P may have different sizes within a same device. For example, as part of patterning the nanostructures 55, described above, nanostructures may increase in size as they are arranged closer to the substrate 50. As a result, in the n-type region 50N, the channel regions 54C may be smaller (e.g., less wide) than the channel regions 54B, and the channel regions 54B may be smaller (e.g., less wide) than the channel regions 54A. Likewise, in the p-type region 50P, the channel regions 52C may be smaller (e.g., less wide) than the channel regions 52B, and the channel regions 52B may be smaller (e.g., less wide) than the channel regions 52A. The patterning processes may further round edges (e.g., corners) of the channel regions 52 and 54.

FIGS. 30A-30C illustrate cross-sectional views of a device according to some alternative embodiments. FIGS. 30A illustrates reference cross-section A-A′ illustrated in FIG. 1. FIG. 30B illustrates reference cross-section B-B′ illustrated in FIG. 1. FIG. 30C illustrates reference cross-section C-C′ illustrated in FIG. 1. In FIGS. 30A-30C, like reference numerals indicate like elements formed by like processes as the structure of FIGS. 27A-27C. For example, the structures of FIGS. 30A-30C includes isolation structures 68 comprising an inner STI region 68C that is surrounded by a second liner layer 68B and an STI hard mask 68D. The STI hard mask 68D may have thickness T5 (see FIG. 29A) as described above. However, in FIGS. 30A-30C, the STI hard mask 68D may be removed from regions outside of the gate structures 100/102. For example, during various processing steps (e.g., as part of patterning the dummy gates), described above, exposed regions of the STI hard mask 68D may be completely removed. As such, the cross-section C-C′ may not include the STI hard mask 68D (see FIG. 30C), and the there is no STI hard mask 68D remaining directly under the first ILD 96. In such embodiments, the CESL 94 may be in direct contact with portions of the inner STI region 68C and the first and second liners 68A/68B.

In various embodiments, isolation regions are formed between and around fins of a transistor to provide isolation between various active regions of the transistors. Protective liners may be formed to cover sidewalls, a bottom surface, and a top surface of the isolation region to reduce isolation loss during subsequent cleaning and/or etching processes that are performed to fabricate the transistors. The outer, protective liners may be nitride layers when the inner, isolation region is made of an oxide. In this manner, the protective liners can provide etch selectivity to the encapsulated isolation regions and reduce isolation loss (e.g., STI loss) during subsequently applied cleaning/etching processes. As a result, manufacturing defects can be reduced, and electrical performance of the resulting device can be improved.

In an embodiment, a device includes a first semiconductor fin and a second semiconductor fin and an isolation structure between the first semiconductor fin and the second semiconductor fin, the isolation structure comprising: an inner shallow trench isolation (STI) region; a first liner layer along sidewalls and a bottom surface of the inner STI region; and a STI hard mask on a top surface of the inner STI region, wherein the STI hard mask and the first liner layer each comprise a higher concentration of nitrogen than the inner STI region. The device also includes a plurality of nanostructures over the first semiconductor fin; and a gate structure over the isolation structure and the first semiconductor fin, wherein the gate structure surrounds each of the plurality of nanostructures. Optionally, in some embodiments, the isolation structure further comprises a second liner layer along sidewalls and a bottom surface of the inner STI region, wherein the second liner layer is disposed between the first semiconductor fin and the first liner layer. Optionally, in some embodiments, the first liner layer has a higher concentration of nitrogen than the second liner layer. Optionally, in some embodiments, the second liner layer comprises: a silicon liner layer; and an oxide liner layer over the silicon liner layer. Optionally, in some embodiments, the first liner layer has a different material composition than the STI hard mask. Optionally, in some embodiments, the STI hard mask has a nitrogen concentration in a range of 28 at % to 38 at %. Optionally, in some embodiments, the first liner layer has a nitrogen concentration in a range of 4 at % to 14 at %.

In an embodiments, a device includes a semiconductor fin; a plurality of nanostructures over the semiconductor fin; first and second source/drain regions in the semiconductor fin, the plurality of nanostructures extending between the first and second source/drain regions; a shallow trench isolation (STI) region along a sidewall of the semiconductor fin; a nitride liner under the STI region, the nitride liner covering a bottom surface and sidewalls of the STI region; a nitride hard mask over the STI region, the nitride hard mask covering a top surface of the STI region; and a gate structure surrounding the plurality of nanostructures, the gate structure overlapping a first portion of the nitride hard mask. Optionally, in some embodiments, the device further includes an oxide liner under the nitride liner, the oxide liner covering the bottom surface and sidewalls of the STI region. Optionally, in some embodiments, the device further includes a dielectric layer around the gate structure, the dielectric layer overlapping a second portion of the nitride hard mask. Optionally, in some embodiments, the first portion of the nitride hard mask has a first thickness, wherein the second portion of the nitride hard mask has a second thickness, and wherein the first thickness is less than the second thickness. Optionally, in some embodiments, the nitride hard mask has a different material composition than the nitride liner. Optionally, in some embodiments, a nitrogen concentration of the nitride hard mask is greater than a nitrogen concentration of the nitride liner.

In an embodiment, a method includes etching a trench in a substrate to define a first semiconductor fin and a second semiconductor fin, the trench being disposed between a first semiconductor fin and a second semiconductor fin; forming a first liner over and along sidewalls of the trench; forming a shallow trench isolation (STI) region over the first liner; forming a hard mask over the STI region, wherein a first material of the hard mask and a second material of the first liner have etch selectivity to a third material of the STI region; and forming a gate structure over and along sidewalls of the first semiconductor fin, wherein the gate structure covers at least a portion of the hard mask. Optionally, in some embodiments, the first liner and the hard mask each have a higher concentration of nitrogen than the STI region. forming the first liner and forming the STI region comprises: depositing a first liner layer over and along sidewalls of the trench; depositing an insulating material over the first liner layer; and after depositing the insulating material, etching back the first liner layer to form the first liner and etching back the insulating material to form the STI region. Optionally, in some embodiments, forming the hard mask comprises forming the hard mask after etching back the first liner layer to form the first liner and etching back the insulating material to form the STI region. Optionally, in some embodiments, forming the hard mask comprises: depositing a second liner layer over a top surface of the first semiconductor fin, over sidewalls of the first semiconductor fin, and over a top surface of the STI region; and removing a first portion of the second liner layer, the first portion of second liner layer being disposed over the top surface of the first semiconductor fin; and removing second portions of the second liner layer, the second portions of the second liner layer being disposed on sidewalls of the first semiconductor fin, wherein after removing the second portions of the second liner layer, a third portion of the second liner layer defines the hard mask, the third portion of the second liner layer being disposed over the top surface of the STI region. Optionally, in some embodiments, removing the first portion of the second liner layer comprises: depositing a mask over the second liner layer; planarizing the mask to expose the first portion of the second liner layer; etching the first portion of the second liner layer while covering the second portions and the third portion of the second liner layer with the mask; and removing the mask. Optionally, in some embodiments, depositing the second liner layer comprises a non-conformal deposition process that deposits the first portion of the second liner layer and the third portion of the second liner layer to have a greater thickness than the second portions of the second liner layer, and wherein removing the second portions of the second liner layer comprises an isotropic etching process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
patterning a trench between a first semiconductor fin and a second semiconductor fin, wherein a first multi-layer stack overlaps the first semiconductor fin, the first multi-layer stack comprising first nanostructures alternatingly stacked with second nanostructures;
forming an isolation structure in the trench, wherein forming the isolation structure comprises:
forming a first liner layer along sidewalls and a bottom surface of the trench;
forming an inner shallow trench isolation (STI) region over the first liner layer in the trench;
forming a STI hard mask on a top surface of the inner STI region, wherein the STI hard mask and the first liner layer each have a higher concentration of nitrogen than the inner STI region;
forming a dummy gate over and along sidewalls of the first multi-layer stack; and
replacing the dummy gate and the second nanostructures with a functional gate stack, the functional gate stack surrounding each of the first nanostructures.

2. The method of claim 1, wherein forming the isolation structure further comprises a second liner layer along sidewalls and a bottom surface the trench prior to forming the first liner layer, wherein the first liner layer is formed over the second liner layer.

3. The method of claim 2, wherein the first liner layer has a higher concentration of nitrogen than the second liner layer.

4. The method of claim 1, wherein forming the STI hard mask comprises:
depositing a third liner layer over and along sidewalls of the first multi-layer stack using a non-conformal deposition process, wherein the third liner layer further covers a top surface of the inner STI region;
forming a patterned hard mask over the third liner layer, wherein the patterned hard mask exposes a first portion of the patterned hard mask that is disposed over the first multi-layer stack;
removing the first portion of third liner layer;
removing the patterned hard mask; and
after removing the patterned hard mask, removing second portions of the third liner layer that is disposed on sidewalls of the first multi-layer stack to define the STI hard mask.

5. The method of claim 4, wherein the non-conformal deposition process is a plasma enhanced chemical vapor deposition (PECVD) process.

6. The method of claim 1, wherein the STI hard mask has a nitrogen concentration in a range of 28 at % to 38 at %.

7. The method of claim 6, wherein the first liner layer has a nitrogen concentration in a range of 4 at % to 14 at %.

8. A method comprising:
forming a first multi-layer stack over a first semiconductor fin and a second multi-layer stack over a second semiconductor fin, wherein the first multi-layer stack comprises first semiconductor nanostructures alternatingly stacked with first dummy nanostructures, and wherein the second multi-layer stack comprises second semiconductor nanostructures alternatingly stacked with second dummy nanostructures;
depositing a first dielectric material between the first semiconductor fin and the second semiconductor fin;
depositing a first nitride liner over and along sidewalls of the first multi-layer stack, wherein the first nitride liner comprises an upper portion having a first thickness over the first multi-layer stack, a sidewall portion having a second thickness along a sidewall of the first multi-layer stack, and a bottom portion having a third thickness, wherein the first thickness and the third thickness are each greater than the second thickness;
removing a first portion of the first nitride liner from over the first multi-layer stack while masking the sidewall portion and the bottom portion of the first nitride liner; and
after removing the first portion of the first nitride liner, removing the sidewall portion of the first nitride liner to define a nitride hard mask from the bottom portion of the first nitride liner, wherein the nitride hard mask covers the first dielectric material; and
replacing the first dummy nanostructures with a gate stack around each of the first semiconductor nanostructures.

9. The method of claim 8, further comprising:
prior to depositing the first dielectric material, depositing a second nitride liner along sidewalls of the first semiconductor fin and the second semiconductor fin, wherein the second nitride liner separates the first dielectric material from the first semiconductor fin and the second semiconductor fin.

10. The method of claim 9, wherein the first nitride liner and the second nitride liner each have a higher nitrogen concentration than the first dielectric material.

11. The method of claim 9, wherein forming the first dielectric material comprises an annealing process that diffuses nitrogen from the second nitride liner into the first dielectric material.

12. The method of claim 8, wherein the gate stack overlaps the nitride hard mask.

13. The method of claim 8 wherein depositing the first nitride liner comprises a plasma- based process.

14. The method of claim 13, wherein the plasma-based process is a plasma enhanced chemical vapor deposition (PECVD) process.

15. The method of claim 8 further comprising:
replacing the second dummy nanostructures with the gate stack, wherein the gate stack is disposed around each of the second semiconductor nanostructures.

16. The method of claim 8, wherein removing the first portion of the first nitride liner from over the first multi-layer stack comprises an anisotropic etch process.

17. The method of claim 16, wherein removing the sidewall portion of the first nitride liner comprises an isotropic etch process.

18. A method comprising:
etching a trench in a substrate to define a first semiconductor fin and a second semiconductor fin;
forming a first liner in the trench;
forming a shallow trench isolation (STI) region over the first liner, wherein the first liner covers sidewalls of the STI region;
forming a hard mask over a top surface of the STI region and a top surface of the first liner, wherein a first material of the hard mask and a second material of the first liner have a higher nitrogen concentration than a third material of the STI region; and
forming a gate structure over and along sidewalls of the first semiconductor fin, wherein the gate structure at least partially covers the hard mask.

19. The method of claim 18, wherein forming the first liner and forming the STI region comprises:
depositing a first liner layer over and along sidewalls of the trench;
depositing an insulating material over the first liner layer; and
after depositing the insulating material, etching back the first liner layer to form the first liner and etching back the insulating material to form the STI region.

20. The method of claim 19, wherein forming the hard mask comprises forming the hard mask after etching back the first liner layer to form the first liner and etching back the insulating material to form the STI region.
